(19) United States
(12) Patent Application Publication
(10) Pub. No.: US 2014/0009877 A1
(43) Pub. Date: Jan. 9, 2014

(54) PORTABLE ELECTRONIC APPARATUS

(71) Applicants: Atsushi Okamoto, Minoh-shi (JP); Kenjiro Okamoto, Higashiosaka-shi (JP); Keisuke Nonaka, Osaka-shi (JP); Akito Iwai, Osaka-shi (JP); Kotaro Nakamura, Daito-shi (JP); Nobuyuki Kitamura, Osaka-shi (JP)

(72) Inventors: Atsushi Okamoto, Minoh-shi (JP); Kenjiro Okamoto, Higashiosaka-shi (JP); Keisuke Nonaka, Osaka-shi (JP); Akito Iwai, Osaka-shi (JP); Kotaro Nakamura, Daito-shi (JP); Nobuyuki Kitamura, Osaka-shi (JP)

(73) Assignee: KYOCERA CORPORATION, Kyoto-shi, Kyoto (JP)

(21) Appl. No.: 13/996,467

(22) PCT Filed: Dec. 15, 2011
(86) PCT No.: PCT/JP2011/079013

§ 371 Date: Sep. 4, 2013

(30) Foreign Application Priority Data
Dec. 21, 2010 (JP) 2010-284672
Dec. 21, 2010 (JP) 2010-284673
Jan. 26, 2011 (JP) 2011-013818
Jan. 26, 2011 (JP) 2011-013820
Jan. 27, 2011 (JP) 2011-015013

(51) Int. Cl. H05K 5/02

(52) U.S. Cl. CPC H05K 5/0226
USPC 361/679.01

(57) ABSTRACT

The portable apparatus comprises a first casing 1 and a second casing 2 slidably connected to each other by a connecting member. The connecting member and one of the casings 2 have opposed surfaces formed with a sliding-contact surface 311 and a sliding-contact receiving surface 211, to slide against each other in a process of shifting from a second opened state to a closed state, to thereby displace from a position in a sliding direction relative to the connecting member in the second opened state to a predetermined relative position in the closed state.

### TECHNICAL FIELD

The present invention relates to a portable electronic apparatus formed by connecting a pair of casings to each other.

### BACKGROUND ART

Conventionally, in a portable electronic apparatus formed by connecting a pair of casings to each other, there is known a portable electronic apparatus in which a display surface is disposed on each of the casings, and a user can be provided with many pieces of information through both the display surfaces.

In such a portable electronic apparatus, for example, sides of the pair of casings are connected to each other by a link member, and both the casings move relative to each other by turning action of the link member between a one-face exposed state (closed state) in which the pair of casings are overlapped on each other, a display surface (first display surface) of the lower casing (first casing) is covered by the upper casing (second casing), and only the display surface (second display surface) of the second casing is exposed, and a both-face exposed state (opened state) in which the second casing moves relative to the first casing, and the display surfaces of both the casings are exposed on the same plane.

According to such a portable electronic apparatus, since the first display surface and the second display surface are aligned on the same plane in the opened state, it is possible to combine the two display surfaces as one large screen and to display an image on the large screen.

In the portable electronic apparatus in which the pair of casings are connected to each other by a link mechanism, there is proposed a portable electronic apparatus in which a keyboard is disposed on a surface of the first casing and a display is disposed on a surface of the second casing, and which is capable of setting two states including: a closed state in which the surface of the first casing is covered by a back surface of the second casing, and only the surface of the second casing is exposed; and a tilted state in which the surface of the second casing is inclined by an opening angle of 90° or more and less than 180° with respect to the surface of the first casing, and the surfaces of both the casings are exposed.

In the above-described portable electronic apparatus, it is possible to employ a configuration in which a slide mechanism is interposed between both the casings, and the casings are slid in directions approaching each other in the opened state. However, in such a portable electronic apparatus, both the casings can slide not only in the opened state but also in the closed state, and there is a problem that a position of one of the casings becomes uncertain with respect to the other casing.

### SUMMARY OF THE INVENTION

In a first portable electronic apparatus according to the present invention, the apparatus comprises a first casing and a second casing connected to each other by a connecting member and a slide mechanism interposed between the connecting mechanism and one of the casings. The apparatus is possible to selectively set at least three states including: a closed state wherein a surface of the first casing is covered by a back surface of the second casing, and a surface of the second casing is exposed; a first opened state wherein the second casing is moved from the closed state by turning motion of the connecting member, and surfaces of both the casings are exposed on a same plane; and a second opened state wherein motion of the slide mechanism causes both the casings to approach each other from the first opened state while the surfaces of both the casings are exposed on the same plane.

In the portable electronic apparatus, the connecting member and one of the casings have opposed surfaces formed with a sliding-contact surface and a sliding-contact receiving surface, to slide against each other in a process of shifting from a second opened state to a closed state, to thereby displace from a position in a sliding direction relative to the connecting member in the second opened state to a predetermined relative position in the closed state.

In a second portable electronic apparatus according to the present invention, the apparatus comprises a first casing and a second casing connected to each other by a connecting member and a slide mechanism interposed between the connecting mechanism and one of the casings. The apparatus is possible to selectively set at least three states including: a closed state wherein a surface of the first casing is covered by a back surface of the second casing, and a surface of the second casing is exposed; a first opened state wherein the second casing is moved from the closed state by turning motion of the connecting member, and surfaces of both the casings are exposed on a same plane; and a second opened state wherein motion of the slide mechanism causes both the casings to approach each other from the first opened state while the surfaces of both the casings are exposed on the same plane.

In the portable electronic apparatus, opposed surfaces of the connecting member and the one casing in the closed state are provided with a protrusion and a recess which engage with each other in a direction intersecting with a sliding direction of the slide mechanism in the closed state.

More specifically, the protrusion is formed on the one casing, and the recess is formed in the connecting member.

In a third portable electronic apparatus according to the present invention, the apparatus comprises a first casing and a second casing connected to each other by a connecting mechanism. The apparatus is possible to selectively set at least two states including: a closed state wherein a surface of the first casing is covered by a back surface of the second casing, and a surface of the second casing is exposed; and a tilted state in which the second casing is moved from the closed state by turning action of the connecting mechanism, the surface of the second casing is inclined by an opening angle of 90° or more and less than 180° with respect to the surface of the first casing, and the surfaces of both the casings are exposed.

A cam mechanism is incorporated in the connecting mechanism, the cam mechanism includes a pair of cam pieces which rotate relative to each other as both the casings relatively move between the closed state and the tilted state, and a spring which brings cam faces of both the cam pieces into contact with each other under pressure, a cam curve of the cam mechanism includes a peak to function in a shifting process from the closed state to the tilted state, and a valley to function in the tilted state, a torque generated in the cam mechanism at an apex of the peak is set to a value greater than a first torque value T1 which is applied to the cam mechanism by a weight of the first casing, and a torque generated by the cam mechanism in the closed state is set to a second torque value T2 which is smaller than the first torque value T1.

In a fourth portable electronic apparatus according to the present invention, the apparatus comprises a first casing and a second casing connected to each other by a connecting member. The apparatus is possible to selectively set at least two states including: a closed state wherein a surface of the first casing is covered by a back surface of the second casing, and a surface of the second casing is exposed; and a tilted state wherein the second casing is moved from the closed state by turning action of the connecting member, the surface of the second casing is inclined by an opening angle of 90° or more and less than 180° with respect to the surface of the first casing, and the surfaces of both the casings are exposed.

Here, a flank is formed on a lower end of the back surface of the second casing, the lower end of the back surface moves along the surface of the first casing when shifting from the closed state to the tilted state, and the flank is inclined in a direction separating from the surface of the first casing in the closed state.

In a fifth portable electronic apparatus according to the present invention, the apparatus comprises a first casing and a second casing connected to each other by a connecting mechanism. The apparatus is possible to selectively set at least two states including: a closed state wherein a surface of the first casing is covered by a back surface of the second casing, and a surface of the second casing is exposed; and a tilted state wherein the second casing is moved from the closed state by turning action of the connecting mechanism, the surface of the second casing is inclined by an opening angle of 90° or more and less than 180° with respect to the surface of the first casing, and the surfaces of both the casings are exposed, wherein

the portable electronic apparatus includes a sensor which detects a state where the connecting mechanism turns by a predetermined angle θ1 in the process of shifting from the closed state to the tilted state, and

a resistance imparting mechanism which imparts a resistance of predetermined magnitude to turning action of the connecting mechanism when the connecting mechanism reaches a turning angle of less than the predetermined angle θ1 in the process of shifting from the closed state to the tilted state.

### BRIEF DESCRIPTION OF THE DRAWINGS

FIG. 1 is a perspective view showing a closed state of a portable electronic apparatus according to an embodiment of the present invention.

FIG. 2 is a perspective view of the portable electronic apparatus which is turned upside down in a closed state.

FIG. 3 is a perspective view showing a tilted state of the portable electronic apparatus.

FIG. 4 is a perspective view of the tilted state of the portable electronic apparatus as viewed from a back surface thereof.

FIG. 5 is a perspective view showing a first opened state of the portable electronic apparatus.

FIG. 6 is a perspective view of the portable electronic apparatus which is turned upside down in the first opened state.

FIG. 7 is a perspective view showing a second opened state of the portable electronic apparatus.

FIG. 8 is a perspective view of the portable electronic apparatus which is turned upside down in the second opened state.

FIG. 9 is an exploded perspective view of the portable electronic apparatus.

FIG. 10 is an exploded perspective view of the portable electronic apparatus which is turned upside down.

FIG. 11 is a perspective view of the portable electronic apparatus which is further partially disassembled from the state shown in FIG. 10.

FIG. 12 is a perspective view of the portable electronic apparatus which is further partially disassembled from the state shown in FIG. 11.

FIG. 13 is a sectional view of the portable electronic apparatus.

FIG. 14 is a perspective view of the portable electronic apparatus which is partially disassembled from the state shown in FIG. 8.

FIGS. 15(a) and 15(b) are other sectional views showing a shift from the first opened state (a) to the second opened state (b) of the portable electronic apparatus.

FIGS. 16(a) and 16(b) are enlarged sectional views of a portion C and a portion D in FIGS. 15(a) and 15(b).

FIGS. 17(a) to 17(c) are sectional views showing a deformed state of a flexible lead in a shift process from the closed state (a) to the second opened state (c) through the first opened state (b).

FIG. 18 is a perspective view showing a pair of protrusions formed on a second casing in the closed state.

FIG. 19 is an enlarged perspective view of a portion E in FIG. 18.

FIG. 20 is a plan view of the pair of protrusions formed on the second casing in the closed state.

FIG. 21 is an enlarged plan view of a portion F in FIG. 20.

FIG. 22 is an enlarged sectional view of essential portions of the second casing at a position where the protrusions are formed.

FIG. 23 is an enlarged sectional view showing a hook structure disposed along opposed portions between the first casing and the second casing in the opened state.

FIG. 24 is a perspective view showing a state where a second display and a front surface cabinet are disassembled from a holder member of the second display.

FIG. 25 is an exploded perspective view of the holder member and a frame member of the second display.

FIGS. 26(a) to 26(d) are a series of side views showing a first half of a process of the portable electronic apparatus from the closed state to the second opened state through the tilted state.

FIGS. 27(a) to 27(d) are a series of side views showing a second half of the process.

FIGS. 28(a) to 28(c) are a series of side views showing a first half of a process of the portable electronic apparatus from the second opened state to the closed state through the tilted state.

FIGS. 29(a) to 29(d) are a series of side views showing a second half of the process.

FIG. 30 is a sectional view showing a state immediately before the protrusion of the second casing engages with a through hole of a connecting member.

FIG. 31 is a sectional view showing a state where the protrusion of the second casing engages with the through hole of the connecting member.

FIG. 32 is a perspective view showing a region of a flank formed on a back surface of the second casing.

FIG. 33 is a diagram schematically showing an inclined state of the flank in the closed state of both the casings.

FIG. 34 is a diagram showing a shift of the second casing in a shift process from the closed state to the tilted state.

FIG. 35 is a front view of a hinge unit.

FIG. 36 is a partially cut-away front view of the hinge unit.

FIG. 37 is a diagram for explaining a first example of a cam curve of a cam mechanism incorporated in the hinge unit and functions thereof.

FIG. 38 is a diagram for explaining a second example of the cam curve of the cam mechanism incorporated in the hinge unit and functions thereof.

FIGS. 39(a) to 39(c) are diagrams for explaining a magnet and operation of a magnetic sensor.

FIG. 40(a) is a side view showing a state where the portable electronic apparatus is placed on a desk in the tilted state.

FIG. 40(b) is a side view showing a state where the portable electronic apparatus is placed on the desk in the second opened state.

### DETAILED DESCRIPTION OF EMBODIMENTS

According to a portable electronic apparatus which is an embodiment of the present invention, as shown in FIGS. 1 to 8, a first casing 1 provided at its surface with a first display surface 11 and a second casing 2 provided at its surface with a second display surface 21 are connected to each other by a connecting mechanism 3. Here, not only images but also characters or video pictures can be displayed on the first display surface 11 and the second display surface 21.

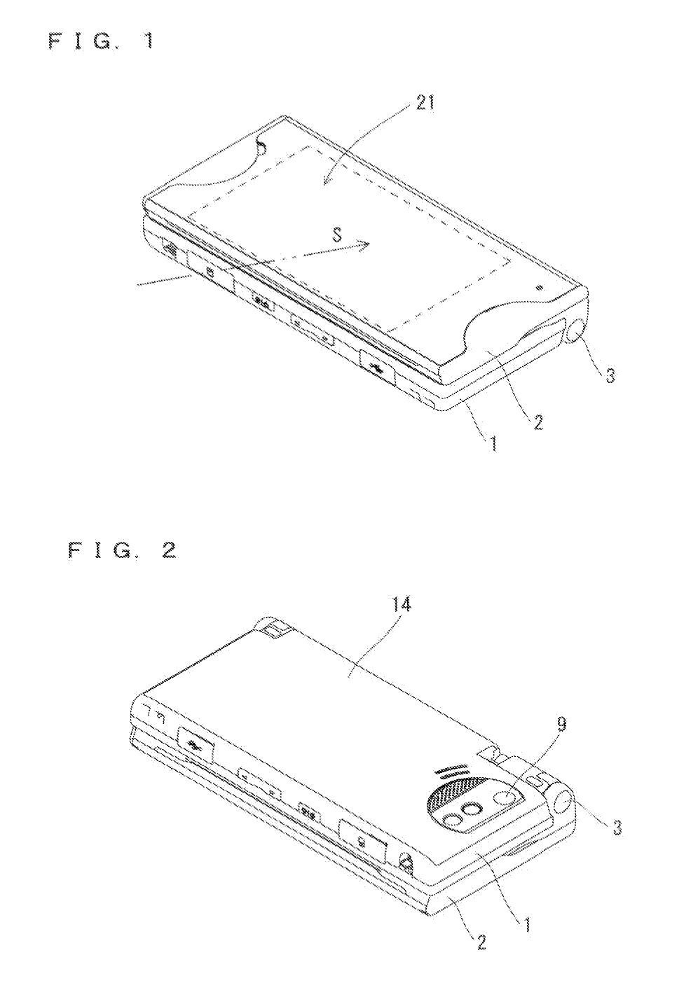

As shown in FIG. 2, a battery lid 14 and a shooting lens 9 are disposed on a back surface of the first casing 1 such that the shooting lens 9 is exposed from the battery lid 14.

In the following description, when various portions of constituent elements of the portable electronic apparatus are specified, “front (near side)”, “rear”, “left” and “right” when the portable electronic apparatus shown in FIG. 1 is viewed from a user's line of sight shown by an arrow S in FIG. 1 are called “front”, “rear”, “left”, and “right” also in other figures regardless of an attitude of the portable electronic apparatus.

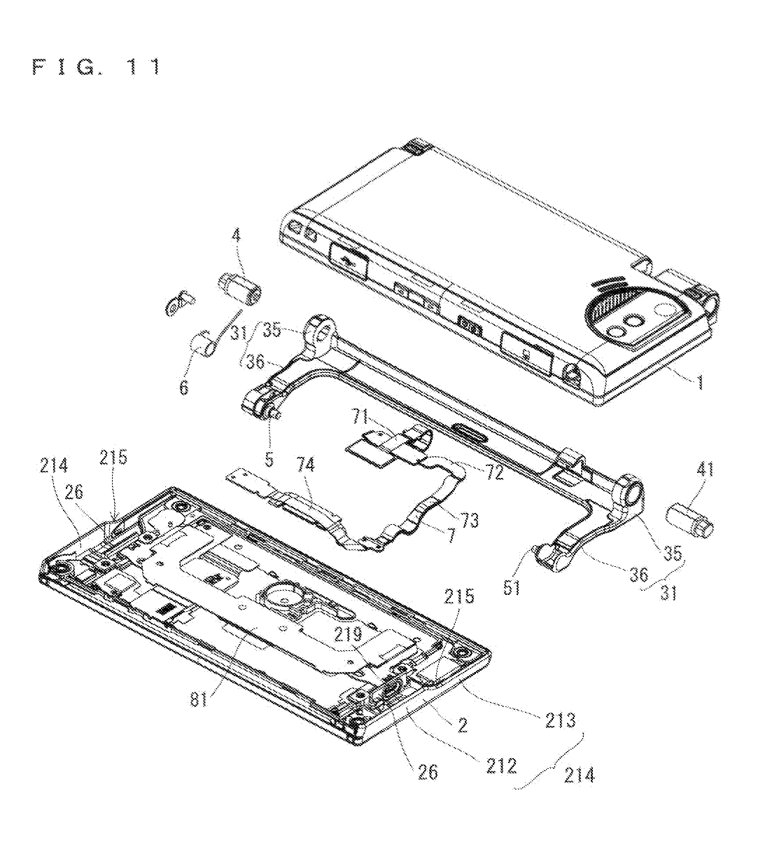

As shown in FIG. 13, a first touch panel 13 and a first display 12 are disposed in the first casing 1 so as to face the first display surface 11, and a camera 91 is disposed so as to face the shooting lens 9. A battery 15 is accommodated in the first casing 1, and the battery 15 can be exchanged by detaching the battery lid 14.

A second touch panel 23 and a second display 22 are disposed in the second casing 2 so as to face the second display surface 21.

A glass plate 16 which is wider than the first display 12 and the first touch panel 13 is disposed on a surface of the first touch panel 13, a surface of the glass plate 16 becomes the first display surface 11, and an image of the first display 12 is displayed on the first display surface 11.

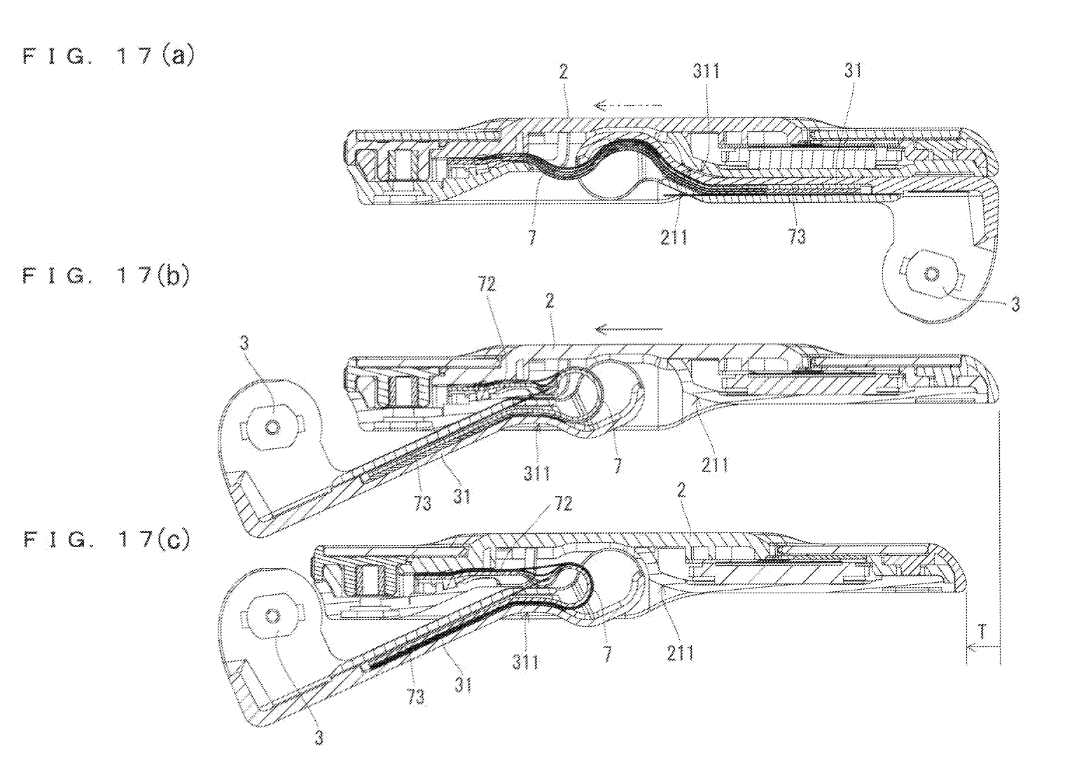

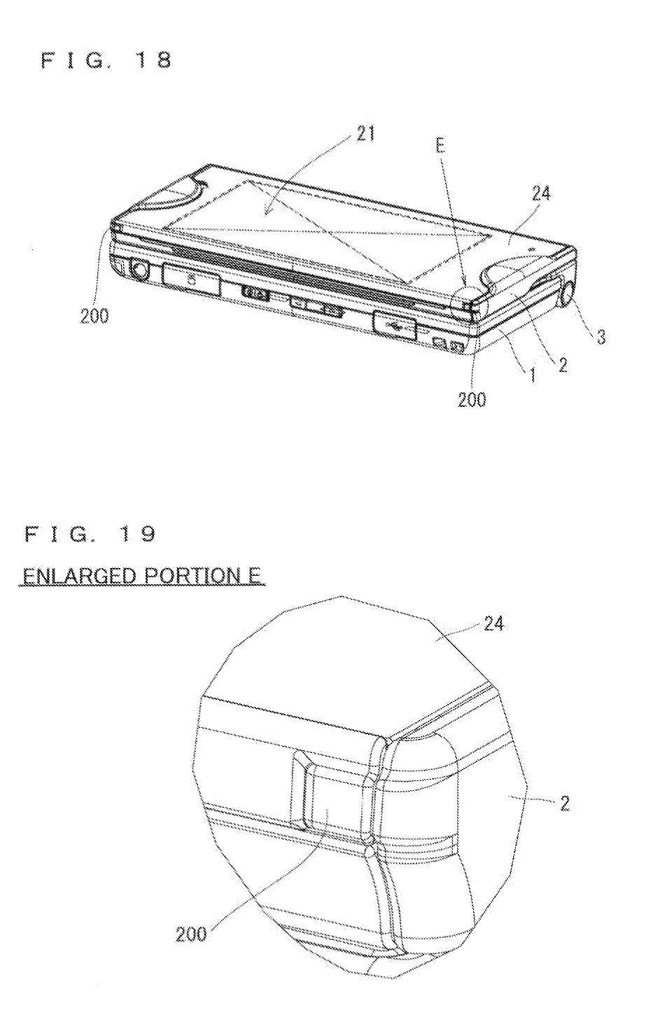

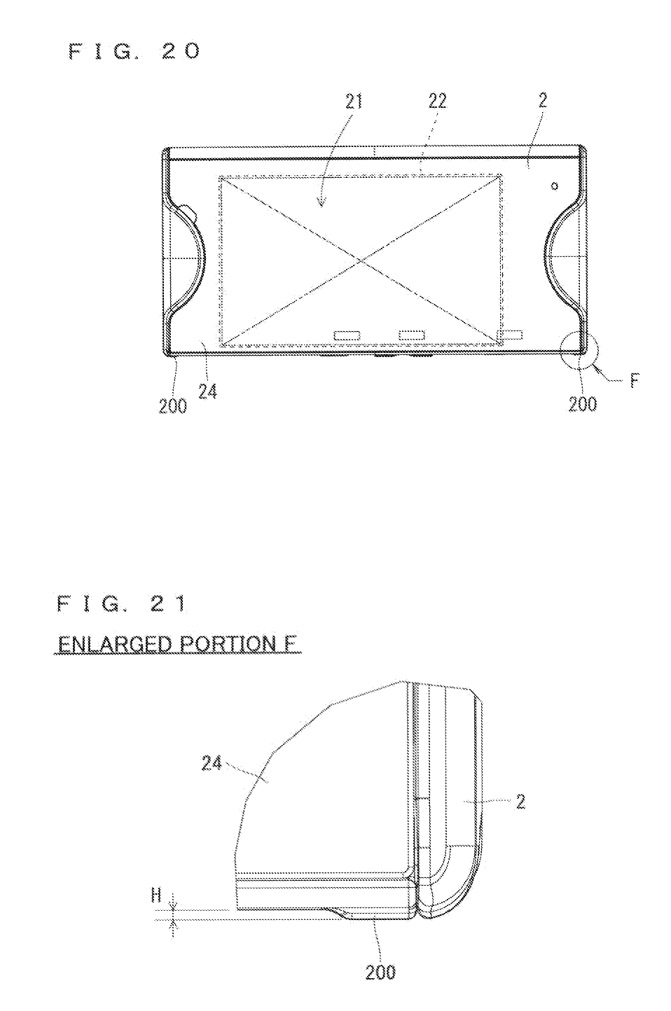

A glass plate 24 which is wider than the second display 22 and the second touch panel 23 is disposed on a surface of the second touch panel 23, a surface of the glass plate 24 becomes the second display surface 21, and an image of the second display 22 is displayed on the second display surface 21 (see FIG. 20).

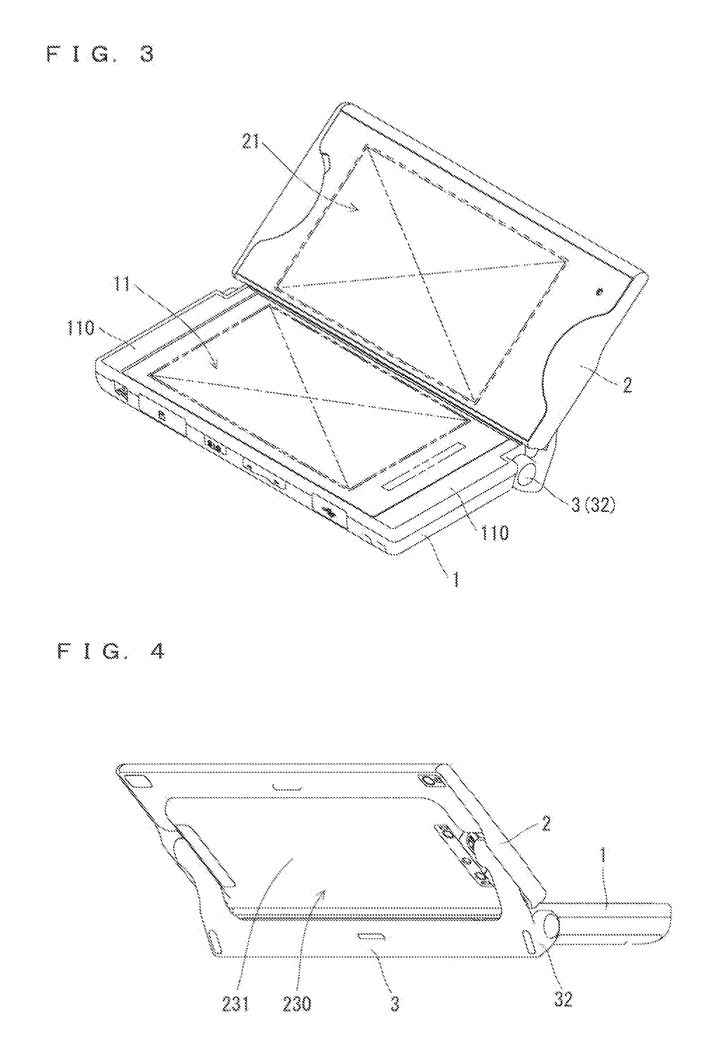

As shown in FIG. 3, surfaces 110 and 110 of the first casing 1 are exposed from both sides of the glass plate 16 disposed on the first casing 1.

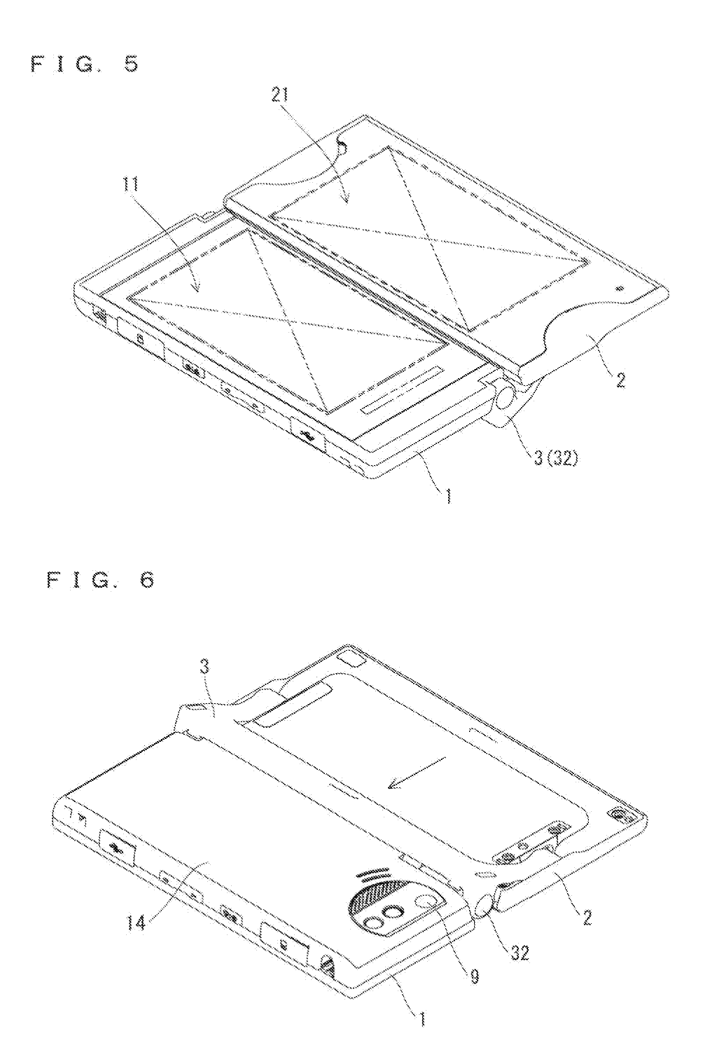

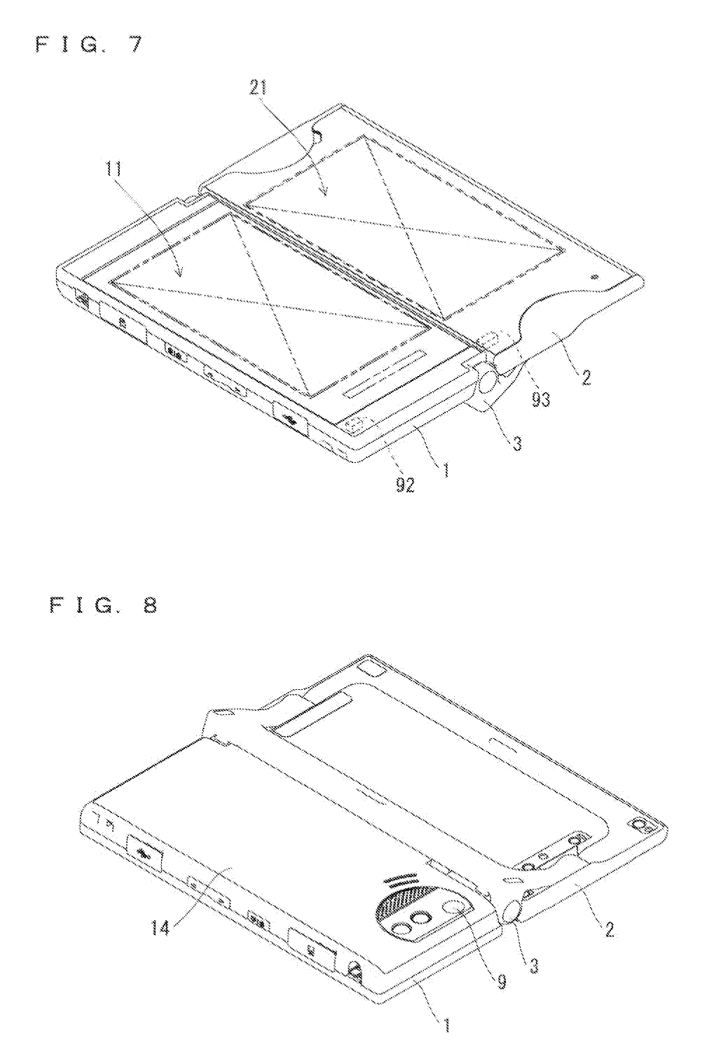

According to the portable electronic apparatus of the present invention, it is possible to selectively set four states including: a closed state wherein the surface of the first casing 1 is covered by the back surface of the second casing 2, and only the surface of the second casing 2 is exposed as shown in FIGS. 1 and 2; a tilted state wherein the surfaces of both the casings 1 and 2 are exposed by moving the second casing 2 rearward and the surface of the second casing 2 is inclined by an opening angle of 90° or more and less than 180° with respect to the surface of the first casing 1 as shown in FIGS. 3 and 4; a first opened state in which the surfaces of both the casings 1 and 2 are exposed on the same plane by turning the second casing 2 rearward as shown in FIGS. 5 and 6; and a second opened state in which the second casing 2 is slid toward the first casing 1 in a state where the surfaces of both the casings 1 and 2 are exposed on the same plane as shown in FIGS. 7 and 8.

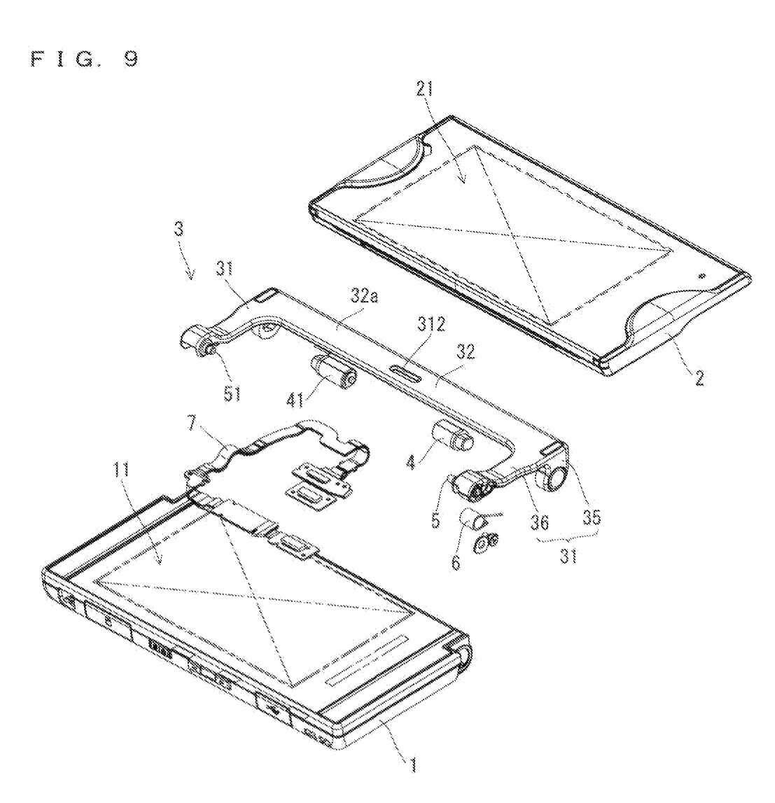

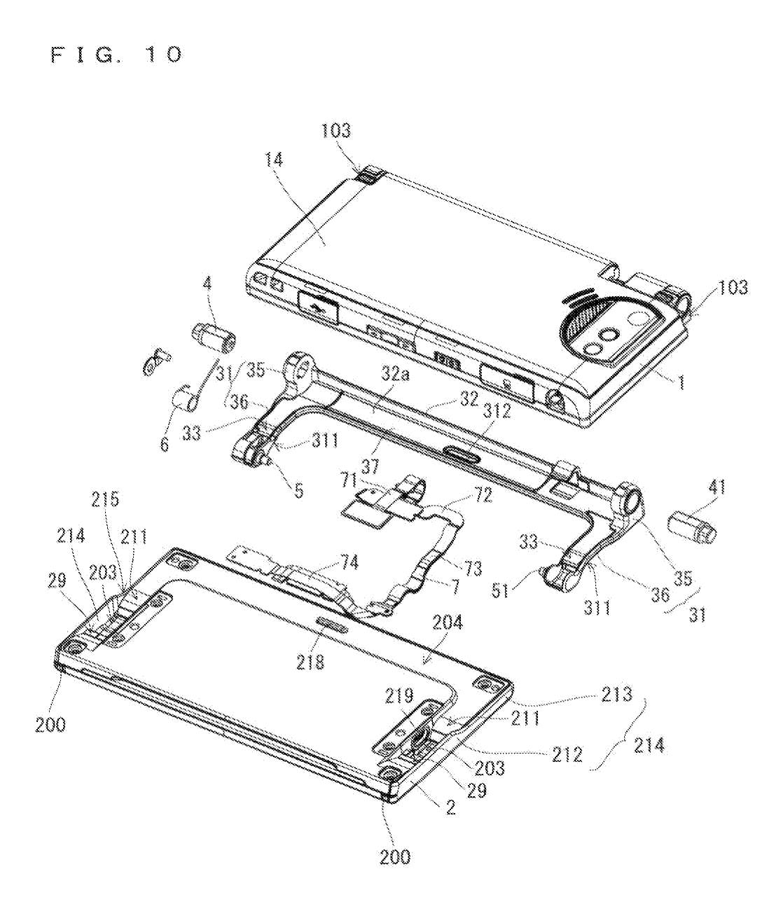

As shown in FIGS. 9 and 10, the connecting mechanism 3 which connects the first casing 1 and the second casing 2 to each other includes a U-shaped connecting member 32 provided with a pair of left and right connecting arms 31 and 31. The connecting arms 31 and 31 extend in a longitudinal direction from both ends of a laterally extending arm-connecting portion 32a.

The connecting arm 31 is configured by a first arm portion 35 and a second arm portion 36 which are bent into an L-shape on a plane orthogonal to display surfaces of both the casings, and the L-shaped angle portions of the first and second arm portions 35 and 36 intersect with each other.

A base end of the right connecting arm 31 (base end of the first arm portion 35) is connected to a rear end of a right side surface of the first casing 1 by a hinge unit 4 in which a cam mechanism having a spring is incorporated as described later, and a base end of the left connecting arm 31 (base end of the first arm portion 35) is connected to a rear end of a left side surface of the first casing 1 by a dummy hinge unit 41 in which a cam mechanism is not incorporated.

A tip end of the right connecting arm 31 (tip end of the second arm portion 36) is connected to a right end of a back surface of the second casing 2 by a first hinge member 5, and a tip end of the left connecting arm 31 (tip end of the second arm portion 36) is connected to a left end of the back surface of the second casing 2 by a second hinge member 51.

The hinge units 4 and 41 configure a first pivot which connects the base end of the connecting arm 31 to the first casing 1, and the hinge members 5 and 51 configure a second pivot which connects the tip end of the connecting arm 31 to the second casing 2. The first pivot and the second pivot are parallel to each other.

A sliding-contact surface 311 is formed on a portion of the second arm portion 36 of each of the connecting arms 31 which is opposed to the second casing 2. A sliding-contact receiving surface 211 which is opposed to the sliding-contact surface 311 in the closed state is formed on the second casing 2.

An electronic component incorporated in the first casing 1 and an electronic component incorporated in the second casing 2 are connected to each other by a flexible lead 7. The flexible lead 7 extends from the inside of the first casing 1 to the inside of the second casing 2 through the inside of the connecting arm 31. The flexible lead 7 includes a first lead portion 71 accommodated in the first casing 1, a second lead portion 72 accommodated in the connecting arm 31, and a third lead portion 73 accommodated in the second casing 2.

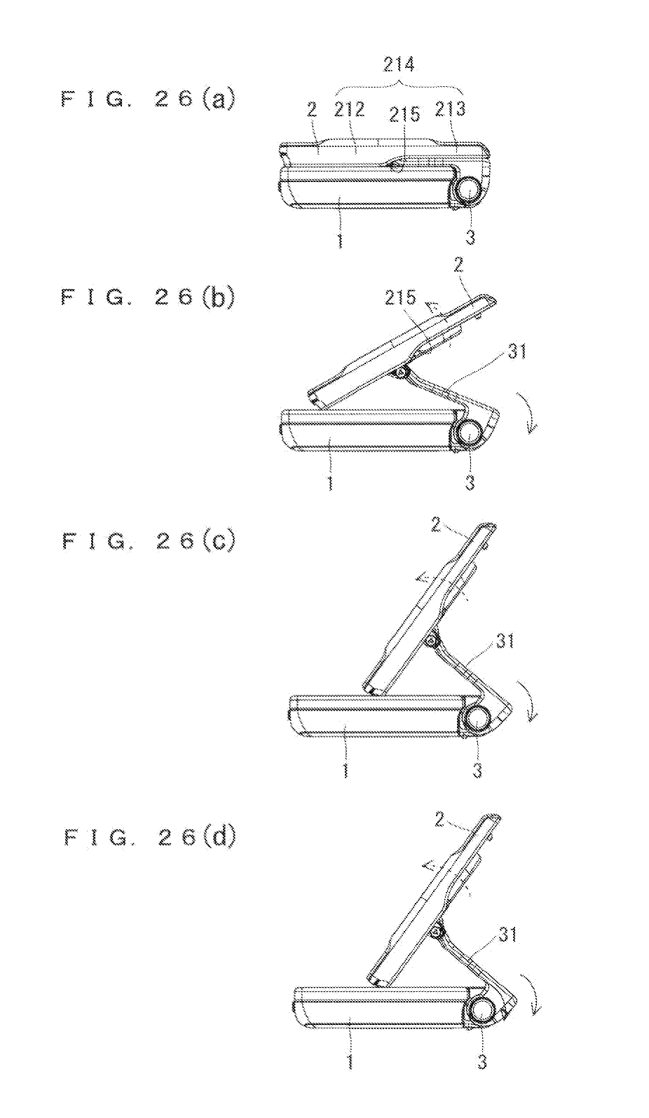

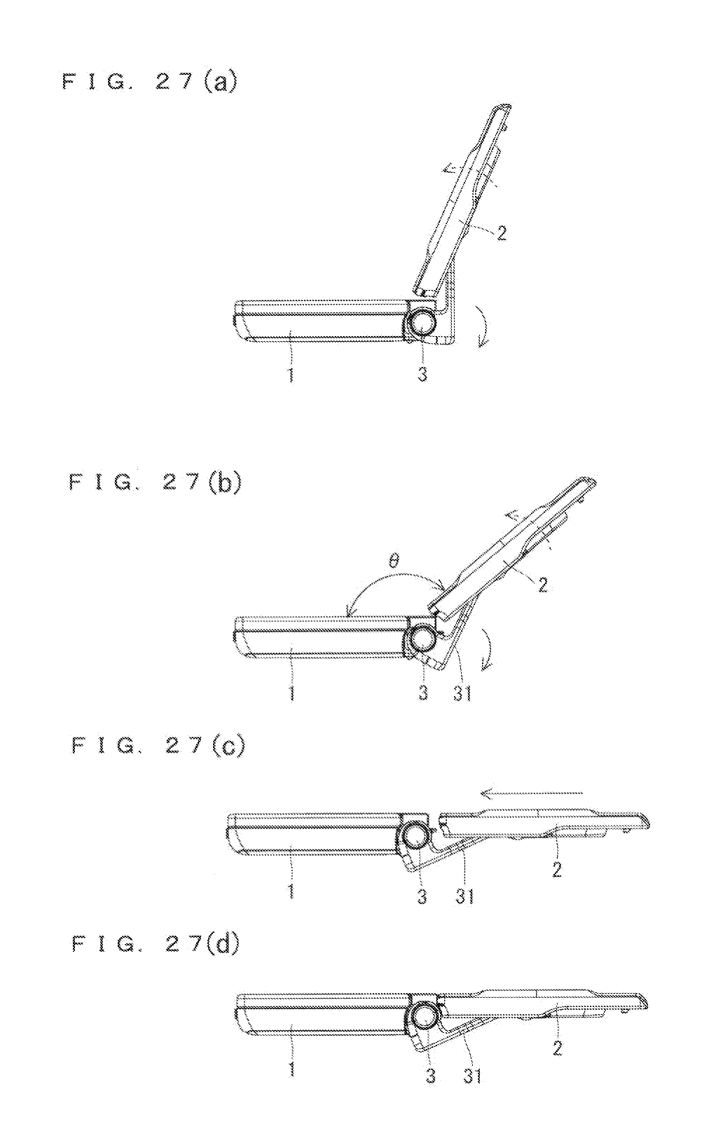

A length of the flexible lead 7 is provided with a minimum necessary margin capable of permitting relative movement between the first casing 1 and the second casing 2. Accordingly, the second casing 2 can carry out a series of relative movements shown in FIGS. 26(a) to 26(d) and FIGS. 27(a) to 27(d) with respect to the first casing 1.

The hinge unit 4 softly latches the connecting member 32 to the first casing 1 in the tilted state shown in FIGS. 3 and 4, and biases the connecting member 32 toward a rotation angle in the tilted state within a constant angle range around a rotation angle in the tilted state. The hinge unit 4 biases the connecting member 32 toward a rotation angle in the first opened state within a constant angle range including the first opened state shown in FIGS. 5 and 6.

In the first opened state shown in FIGS. 5 and 6, the connecting member 32 is received by the first casing 1, thereby holding the connecting member 32 at a rotation angle of the first opened state.

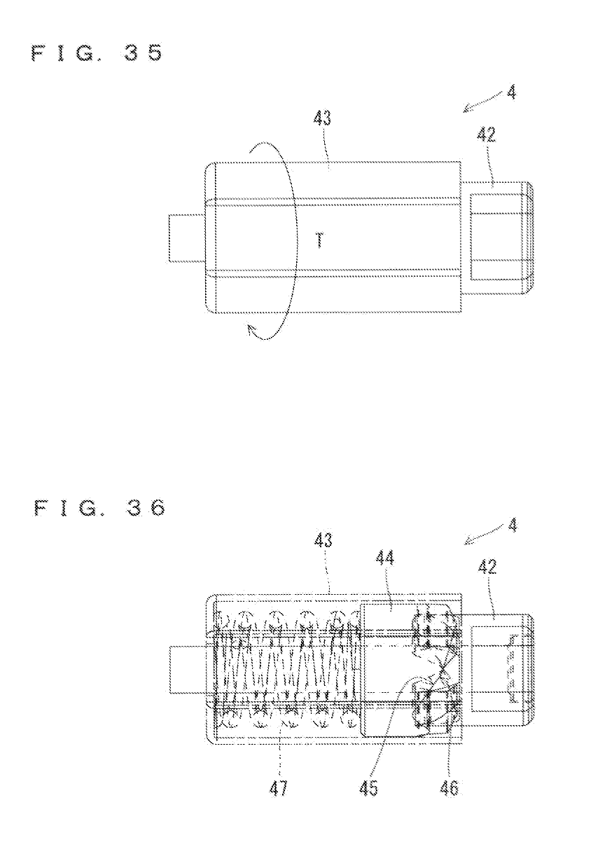

More specifically, as shown in FIGS. 35 and 36, the hinge unit 4 includes a fixed cam piece 42 and a movable cam piece 43 which can move relative to each other, and a cam face 45 formed on the fixed cam piece 42 and a cam face 46 formed on the movable cam piece 43 are opposed to each other.

A spring 47 is interposed between the fixed cam piece 42 and the movable cam piece 43 for bringing cam faces 45 and 46 of both the cam pieces 42 and 43 into contact with each other under pressure. A torque for relatively rotating both the cam pieces 42 and 43 is generated by biasing action of the spring 47 and sliding-contact action of both the cam faces 45 and 46.

The fixed cam piece 42 and the movable cam piece 43 of the hinge unit 4 are respectively connected to the second arm portion 36 of the connecting arm 31 and a side of the first casing 1 shown in FIG. 9.

A cam mechanism including a spring is incorporated in the hinge unit 4 which constitutes the connecting mechanism 3. The hinge unit 4 imparts a torque as a resistance or a biasing force to turning action of the second casing 2 with respect to the first casing 1.

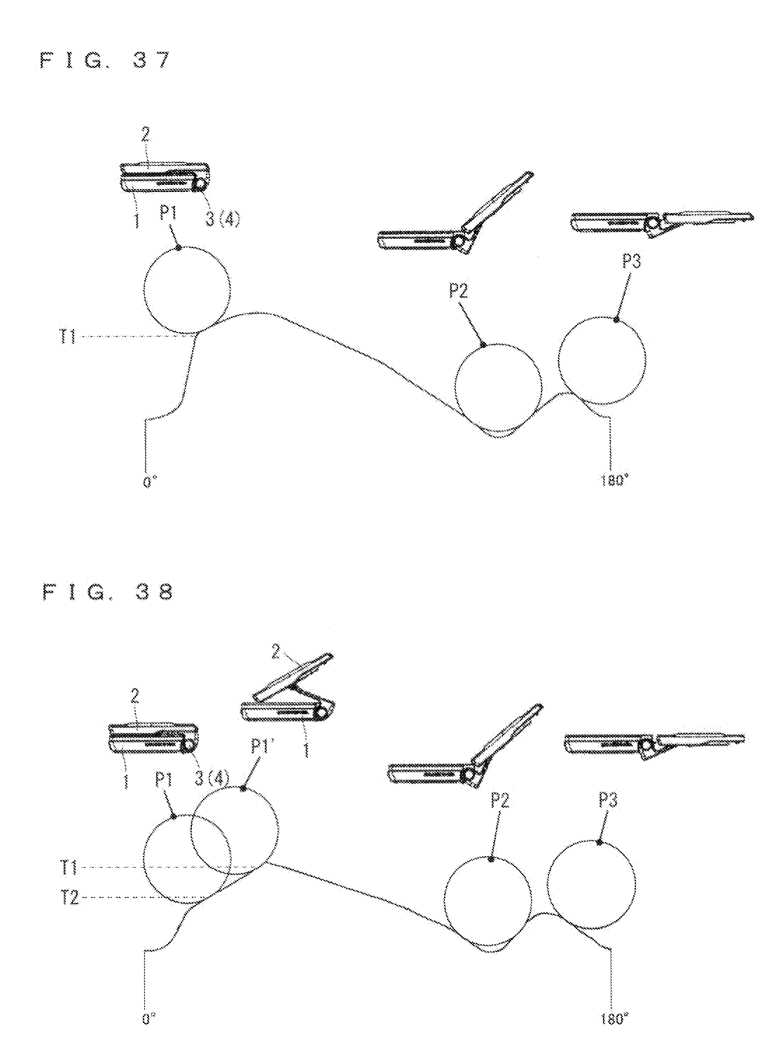

The cam mechanism incorporated in the hinge unit 4 is operated in accordance with a cam curve shown in FIG. 37 or 38. The cam curve includes two peaks and one valley interposed between the two peaks within an angle range of 0° to 180°.

Larger one of the peaks (first peak) on the side of 0° of the cam curve functions in a shifting process from the closed state to the tilted state. In the closed state, an inclined portion (cam state P1) on the side of 0° of the peak holds the first casing 1 and the second casing 2 in the closed state, and after the state passes through an intermediate state between the closed state and the tilted state, the first casing 1 and the second casing 2 are biased toward the tilted state.

The smaller peak (second peak) on the side of 180° of the cam curve functions in a shift process from the tilted state to the first opened state. In the first opened state, the first casing 1 and the second casing 2 are held in the first opened state by an inclined portion (cam state P3) on the side of 180° of the peak.

The first casing 1 and the second casing 2 are held in the tilted state by the valley (cam state P2) of the cam curve.

As described above, the cam mechanism in which the spring is incorporated is connected to the connecting mechanism 3. According to this configuration, the cam mechanism can be operated in accordance with the predetermined cam curve in a shift process from the closed state to the tilted state. In the closed state, both the casings can be biased toward the closed state by the spring. In the tilted state, both the casings can be biased toward the tilted state by the spring.

Accordingly, both the casings are held in the attitude of the closed state or the tilted state with a constant holding force.

In a cam curve of a first example shown in FIG. 37, a torque to be generated by the cam mechanism in the closed state is set slightly greater than a first torque value T1 which is applied to the cam mechanism by a weight of the first casing 1 when only the second casing 2 is grasped and picked up.

In a cam curve in a second example shown in FIG. 38, an inclined portion (cam state P1′) immediately before an apex of the first peak functions in an intermediate state between the closed state and the tilted state. A torque generated by the cam mechanism in the intermediate state between the closed state and the tilted state is set to a value greater than the first torque value T1 which is applied to the cam mechanism by the weight of the first casing 1 when only the second casing 2 is grasped and picked up. A torque which is generated by the cam mechanism in the closed state is set to a second torque value T2 which is smaller than the torque value T1.

When a user intentionally sets the tilted state, a turning force greater than a resistance imparted by the cam mechanism may be applied to the connecting mechanism 3.

Accordingly, a state where the connecting mechanism 3 is turned by a predetermined angle θ1 is detected, and a predetermined apparatus operation in the tilted state is started.

In the portable electronic apparatus, even if only the second casing 2 is grasped and picked up in the closed state, the cam mechanism generates, as drag, a torque which is greater than the first torque value T1 applied to the cam mechanism by the weight of the first casing 1 by the peak of the cam curve. Therefore, both the casings are held in the closed state or in a state slightly opened from the closed state, and the casings are not shifted to the tilted state.

When both the casings are shifted from the closed state to the tilted state, a torque which is greater than the first torque value T1 may be applied to the cam mechanism.

In the closed state, the cam mechanism holds both the casings in the closed state by the second torque value T2 which is smaller than the first torque value T1. Therefore, when an operation for opening both the casings from the closed state toward the tilted state is carried out, since it is only necessary to apply a torque greater than the second torque value T2 to the cam mechanism, its operation force becomes small.

As shown in FIG. 9, a torsion spring 6 is mounted on the first hinge member 5 around its rotation shaft (second pivot), and the torsion spring 6 rotates and biases the second casing 2 in a direction in which an opening angle θ in the tilted state shown in FIG. 27(b) is reduced.

As shown in FIG. 10, accommodating portions 103 and 103 for accommodating the first arm portions 35 and 35 of the connecting arms 31 and 31 of the connecting member 32 are recessed in rear ends of both side surfaces of the first casing 1.

Accommodating portions 204, 203, and 203 for accommodating an arm connecting portion 37 and the second arm portions 36 and 36 of the connecting member 32 are recessed in both sides of the back surface of the second casing 2.

A laterally long through hole 312 is formed in a central portion of the arm-connecting portion 32a of the connecting member 32. A laterally long protrusion 218 is formed on the second casing 2 at a central portion of the accommodating portion 204. The protrusion 218 is for engaging with the through hole 312 in the closed state.

Each of both sidewalls 214 and 214 of the second casing 2 includes a first sidewall portion 212 having a large height from the surface of the second casing 2 toward the first casing 1 in the closed state, and a second sidewall portion 213 having a small height from the surface of the second casing 2 toward the first casing 1. The pair of left and right first sidewall portions 212 and 212 are located on both sides of the accommodating portions 203 and 203 on both sides of the second casing 2.

A finger-rest surface 215 which is inclined with respect to the surface of the first casing 1 in the closed state is formed between an end surface of the first sidewall portion 212 which is opposed to the surface of the first casing 1 and an end surface of the second sidewall portion 213.

As shown in FIG. 10, receiving surfaces 33 for receiving the second casing 2 are formed on portions of both the connecting arms 31 and 31 of the connecting member 32 which are opposed to the second casing 2. Slide surfaces 29 for sliding-contact with the receiving surfaces 33 are formed on both ends of the back surface of the second casing 2.

In the tilted state shown in FIGS. 3 and 4 and in the first opened state shown in FIGS. 5 and 6, the slide surface 29 of the second casing 2 abuts against the receiving surface 33 of the connecting arm 31, and turning action of the second casing 2 with respect to the connecting arm 31 is received. Accordingly, a relative attitude of the second casing 2 with respect to the connecting arm 31 in the tilted state and the first opened state is defined.

As shown in FIG. 12, a U-shaped slide member 83 which can slide in the longitudinal direction is disposed on a sheet metal member 28 disposed in the second casing 2, and a U-shaped support member 81 covering the slide member 83 is fixed to the sheet metal member 28 (see FIG. 14).

As shown in FIG. 12, arm portions 84 and 84 project from both left and right ends of the slide member 83. Slide guide members 82 and 82 are mounted on both left and right ends of the support member 81.

The arm portions 84 and 84 of the slide member 83 are sandwiched between the slide guide members 82 and 82 of the support member 81 and the sheet metal member 28, and the sliding action of the slide member 83 on the sheet metal member 28 in the longitudinal direction is guided.

The first hinge member 5 and the second hinge member 51 respectively penetrate long holes 219 on the second casing 2, and tip ends of the first hinge member 5 and the second hinge member 51 are pivotally supported and connected to both sides of the arm portions 84 and 84 of the slide member 83.

Accordingly, a slide mechanism 8 which makes the second casing 2 slide on the arm portions 84 and 84 of the slide member 83 in the longitudinal direction is configured, and the second casing 2 can slide in the longitudinal direction between the first opened state shown in FIGS. 5 and 6 and the second opened state shown in FIGS. 7 and 8.

In the portable electronic apparatus, the slide mechanism is interposed between both the casings. According to this configuration, a gap between the first display surface and the second display surface in the opened state can be minimized. Therefore, when the two display surfaces are combined as one large screen and an image is displayed on the large screen, one image is not largely cut between the two display surfaces, and continuity of an image can be maintained.

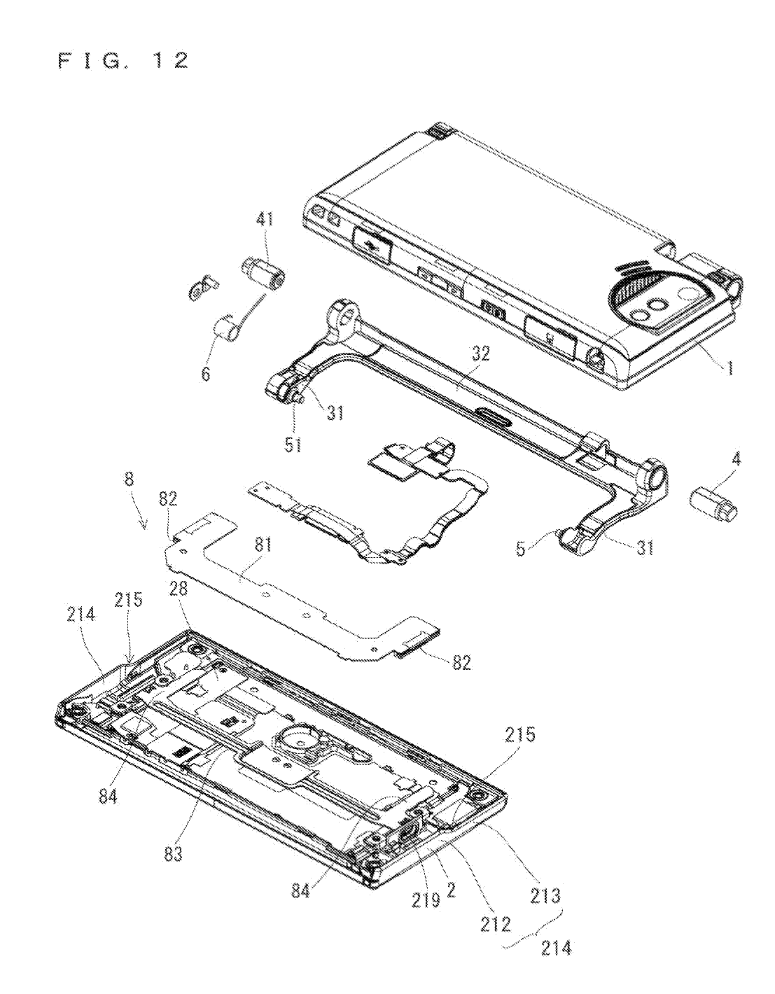

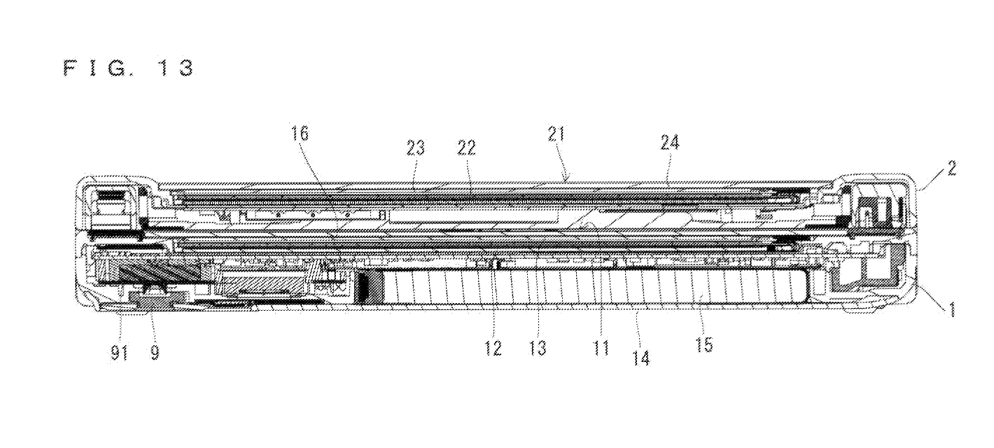

A protrusion 10 and a recess 20 which can engage with and disengage from each other as shown in FIGS. 15(a) and 15(b) and FIGS. 16(a) and 16(b) are respectively formed on a rear end surface of the first casing 1 and in a front end surface of the second casing 2 which are opposed to each other in the first opened state. The protrusion 10 and the recess 20 are disengaged from each other in the first opened state shown in FIGS. 15(a) and 16(a), and the protrusion 10 and the recess 20 engage with each other in the second opened state shown in FIGS. 15(b) and 16(b).

As a result, in the second opened state shown in FIGS. 15(b) and 16(b), the first casing 1 and the second casing 2 are connected to each other by the engagement between the protrusion 10 and the recess 20, and the first display surface 11 and the second display surface 21 are maintained in a state of being aligned on the same plane.

As shown in FIGS. 15(a) and 16(a), in the first opened state, a sufficiently large gap T (e.g., several mm) is provided between the first casing 1 and the second casing 2, but as shown in FIGS. 15(b) and 16(b), in the second opened state, the first casing 1 and the second casing 2 abut against each other or are opposed to each other by a slight distance (e.g., 0.1 mm).

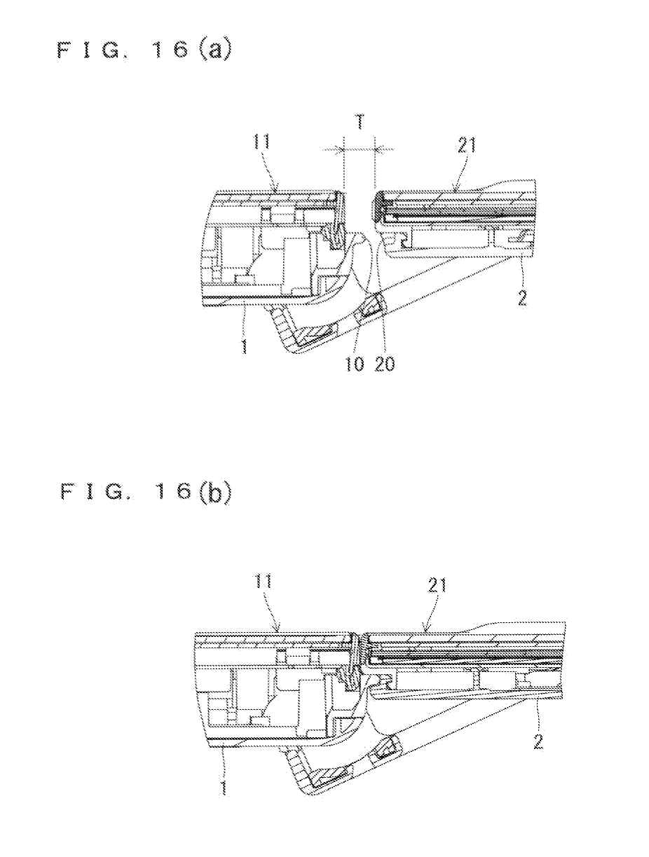

As shown in FIGS. 18 to 21, in the portable electronic apparatus, a pair of protrusions 200 and 200 are formed on both left and right ends of a front end surface of the first casing 1. A projecting height H of the protrusion 200 is about 0.3 mm.

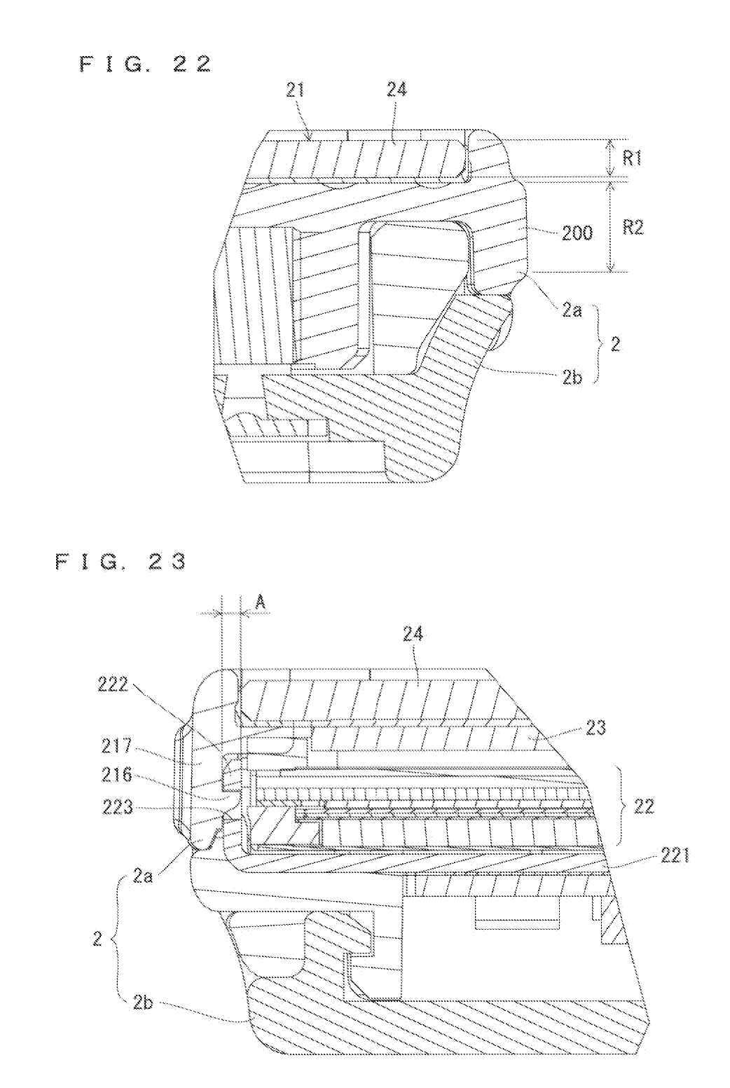

More specifically, as shown in FIG. 22, the second casing 2 is configured by a front surface cabinet 2a and a back surface cabinet 2b which are made of synthetic resin, the pair of protrusions 200 and 200 are formed in a front surface cabinet 2a, and are disposed in a region R2 which is deviated from a thickness region R1 of the glass plate 24 of the front surface cabinet 2a and deviated from the second display 22 in its width direction, as shown in FIG. 20.

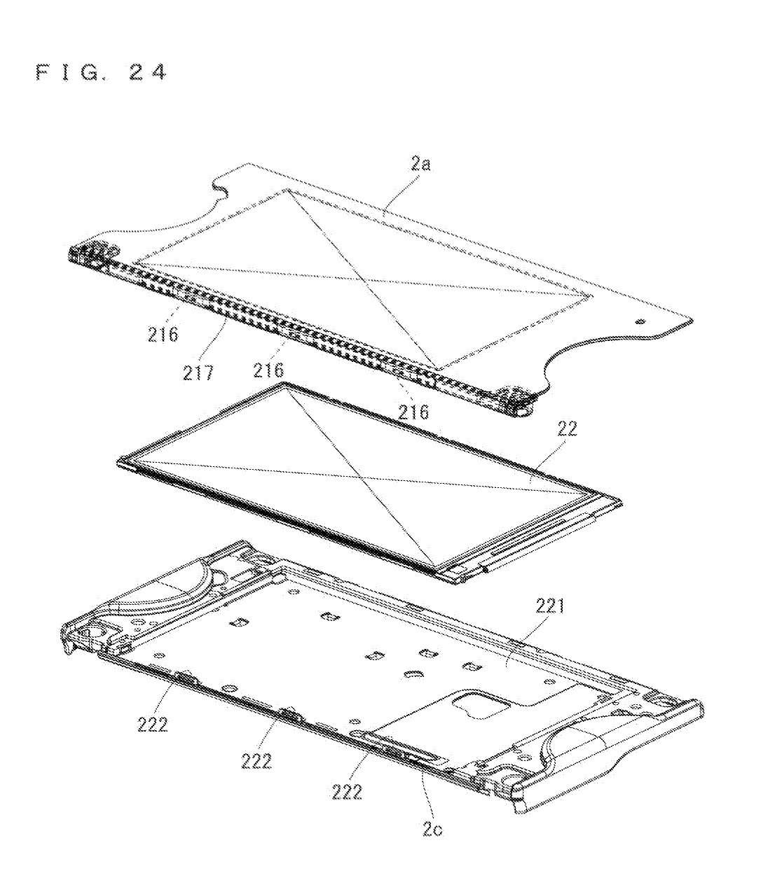

As shown in FIGS. 23 and 24, the second display 22 is held on a holder member 221 made of stainless steel sheet metal (plate thickness of 0.3 mm), and the holder member 221 is latched to the front surface cabinet 2a of the second casing 2.

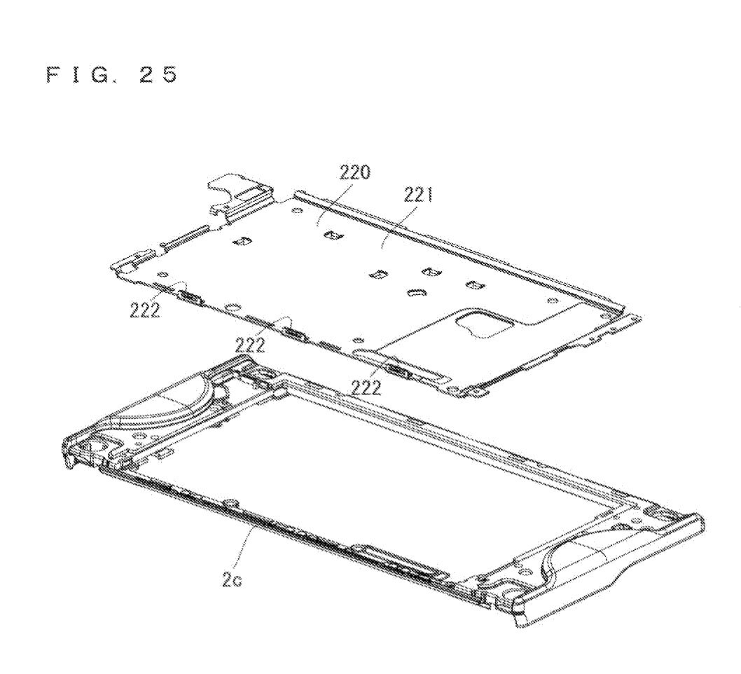

More specifically, the holder member 221 engages with a frame-shaped frame member 2c made of synthetic resin shown in FIG. 25. The second display is placed on a flat plate portion 220. Three engagement receiving pieces 222, 222, and 222 upwardly project from a front end edge of the flat plate portion 220.

As shown in FIGS. 23 and 24, a sidewall 217 extending along a front end edge of the second display 22 is formed on the front surface cabinet 2a of the second casing 2. Three engagement pieces 216, 216, and 216 to be engaged with the three engagement receiving pieces 222, 222, and 222 project from an inner surface of the sidewall 217 toward the second display 22.

As shown in FIG. 23, in the engaged state between the engagement receiving piece 222 and the engagement piece 216, the engagement piece 216 is fitted into a hole 223 formed in the engagement receiving piece 222, thereby latching the holder member 221 to the front surface cabinet 2a of the second casing 2.

For example, an engagement depth (plate thickness of holder member 221) A between the engagement piece 216 and the engagement receiving piece 222 is set to 0.3 mm.

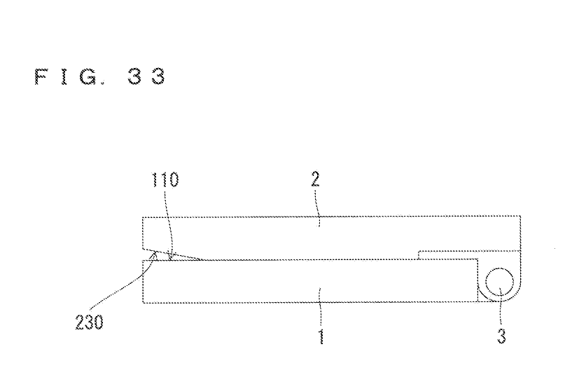

A flank 230 shown in FIG. 33 is formed on a lower end (front end) of a back surface 231 of the second casing 2 shown in FIG. 4. The lower end of the back surface 231 moves along surfaces 110 and 110 of the first casing 1 shown in FIG. 3 when shifting from the closed state to the tilted state. The flank 230 is inclined in a direction separating from the surface of the first casing 1 in the closed state.

As shown by hatch lines in FIG. 32, the flank 230 is formed in a band-shaped region extending in the lateral direction over the entire width of the back surface 231 of the second casing 2.

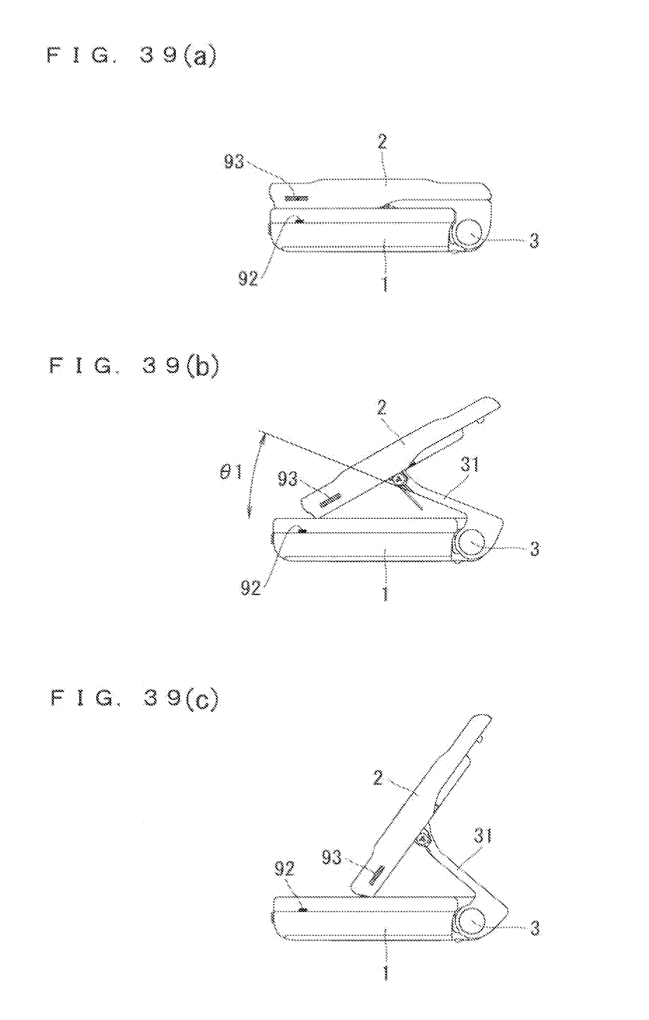

As shown in FIG. 7, a magnetic sensor 92 is incorporated in a right front end of the first casing 1 and a magnet 93 is incorporated in a right front end of the second casing 2. As shown in FIG. 39(a), in the closed state, the magnetic sensor 92 of the first casing 1 and the magnet 93 of the second casing 2 are opposed to and adjacent to each other.

In the portable electronic apparatus, the magnet 93 and the magnetic sensor 92 are disposed at a position where the first casing 1 and the second casing 2 are opposed to each other. Thus, it is possible to detect a shift from the closed state to the tilted state based on a signal obtained from the magnetic sensor, and based on the detection, it is possible to start an apparatus operation, e.g., to startup a liquid crystal display forming the display surface of the first casing 1, in the tilted state.

In the closed state shown in FIG. 39(a), the magnetic sensor 92 strongly receives magnetism from the magnet 93 and is turned ON. When a lower end of the back surface of the second casing 2 slides on the surface of the first casing 1 as shown in FIG. 39(b) and the connecting arm 31 reaches a predetermined rotation angle θ1 (e.g., 21°), the magnetic sensor 92 is turned OFF from the ON state since the magnetic sensor 92 separates from the magnet 93 and magnetism from the magnet 93 is weakened.

As shown in FIG. 39(c), the magnetic sensor 92 maintains the OFF state in a state where the connecting arm 31 exceeds the predetermined rotation angle θ1.

In the portable electronic apparatus, even if, for example, a user grasps only the second casing 2 and picks it up due to action of an unintentional external force of the user and a weight of the first casing 1 acts as a force for opening both the casings and both the casings are opened from the closed state to the tilted state, if the connecting mechanism 3 reaches a turning angle of less than the predetermined angle θ1, a resistance of a predetermined magnitude is imparted to the turning action of the connecting mechanism 3, further turning action of the connecting mechanism 3 is prevented by this resistance, the turning angle of the connecting mechanism 3 does not reach the predetermined angle θ1, and thus the magnetic sensor 92 does not operate.

As a result, an unnecessary apparatus operation is not started, and increase in power consumption is prevented.

A control circuit incorporated in the first casing 1 receives ON/OFF signals from the magnetic sensor 92. When the rotation angle of the connecting arm 31 is less than the predetermined rotation angle θ1 as shown in FIGS. 39(a) and 39(b), apparatus control in the tilted state is not started, and when the rotation angle of the connecting arm 31 becomes equal to or greater than the predetermined rotation angle θ1 as shown in FIGS. 39(b) and 39(c), the apparatus control in the tilted state is started.

When the cam curve of the second example shown in FIG. 38 is employed for the cam mechanism incorporated in the hinge unit 4, the predetermined angle θ1 is set slightly greater than the rotation angle of the connecting arm 31 when both the casings 1 and 2 open to an intermediate state between the closed state and the tilted state by grasping and picking up only the second casing 2.

According to this portable electronic apparatus, it is possible to selectively set four states including: the closed state in which the first casing 1 and the second casing 2 are overlapped on each other and only the second display surface 21 is exposed as shown in FIGS. 1 and 2; the tilted state in which the second casing 2 is moved rearward from the closed state, both the first display surface 11 and the second display surface 21 are exposed, and the second display surface 21 is inclined by the opening angle of 90° or more and less than 180° with respect to the first display surface 11 as shown in FIGS. 3 and 4; the first opened state in which the second casing 2 is turned rearward from the tilted state and both the first display surface 11 and the second display surface 21 are exposed on the same plane as shown in FIGS. 5 and 6; and the second opened state in which the second casing 2 is slid from the first opened state toward the first casing 1 and both the display surfaces 11 and 21 are exposed on the same plane at the position where the first display surface 11 and the second display surface 21 approach each other as shown in FIGS. 7 and 8.

In the closed state shown in FIGS. 1 and 2, the first arm portions 35 and 35 of the connecting arms 31 and 31 are accommodated in the accommodating portions 103 and 103 of the first casing 1 shown in FIG. 10, the arm connecting portion 37 and the second arm portions 36 and 36 of the connecting member 32 are accommodated in the accommodating portions 204, 203, and 203 of the second casing 2, the connecting mechanism 3 does not project from both side surfaces or rear end surfaces of both the casings 1 and 2, and the entire apparatus is accommodated compactly.

In the closed state, as shown in FIG. 18, the front end surface of the first casing 1 and the front end surface of the second casing 2 are aligned, and the protrusions 200 and 200 project forward from the front end surfaces of both the casings 1 and 2.

In any of the tilted state shown in FIG. 3, the first opened state shown in FIG. 5 and the second opened state shown in FIG. 7, a substantially entire portion of the connecting mechanism 3 is hidden on the side of the back surfaces of both the casings 1 and 2, and the projecting portion of the connecting mechanism 3 cannot be easily seen from a user's normal line of sight (arrow S in FIG. 1).

In the second opened state, the first arm portions 35 and 35 of the connecting arms 31 and 31 of the second casing 2 are accommodated in the accommodating portions 103 and 103 of the first casing 1 shown in FIG. 10, and the protrusions 200 and 200 of the second casing 2 are accommodated in the accommodating portions 103 and 103.

As shown in FIGS. 26(a) to 26(d) and FIGS. 27(a) to 27(d), if the second casing 2 is pressed rearward and slightly moved in the closed state shown in FIG. 26(a) in a process of shifting the portable electronic apparatus from the closed state to the second opened state through the tilted state and the first opened state, the second casing 2 is thereafter turned in a counterclockwise direction as shown by arrows of broken lines as shown in FIGS. 26(b) to 26(d) by the biasing action of the torsion spring 6. Accordingly, the connecting arm 31 rotates in a clockwise direction as shown by arrows of solid lines.

Accordingly, the second casing 2 moves rearward while orienting the second display surface 21 upward or diagonally upward.

When the cam curve of the first example shown in FIG. 37 is employed for the cam mechanism incorporated in the hinge unit 4, even if only the second casing 2 is grasped and picked up, both the casings 1 and 2 do not open from the closed state to the tilted state by the weight of the first casing 1.

When both the casings 1 and 2 are to be shifted from the closed state to the tilted state, a torque greater than the first torque value T1 may be applied to the cam mechanism.

When the cam curve of the second example shown in FIG. 38 is employed for the cam mechanism incorporated in the hinge unit 4, if only the second casing 2 is grasped and picked up, although both the casings 1 and 2 slightly open to the intermediate state between the closed state and the tilted state by the weight of the first casing 1, both the casings 1 and 2 are not greatly opened to the tilted state.

When the operation for opening both the casings 1 and 2 from the closed state toward the tilted state is carried out, a torque greater than the second torque value T2 may be applied to the cam mechanism. Therefore, a pressing force required when the second casing 2 is pressed rearward in the closed state shown in FIG. 26(a) becomes small.

Even if both the casings 1 and 2 open to the intermediate state (cam state P1′) between the closed state and the tilted state by grasping and picking up only the second casing 2, since the rotation angle of the connecting arm 31 at that time is smaller than the predetermined angle θ1 shown in FIG. 39(b), the magnetic sensor 92 is not turned OFF. Thus, the apparatus control in the tilted state, e.g., control for starting up the first display is not started.

Therefore, it is possible to avoid a case where power consumption is increased by an unnecessary apparatus operation.

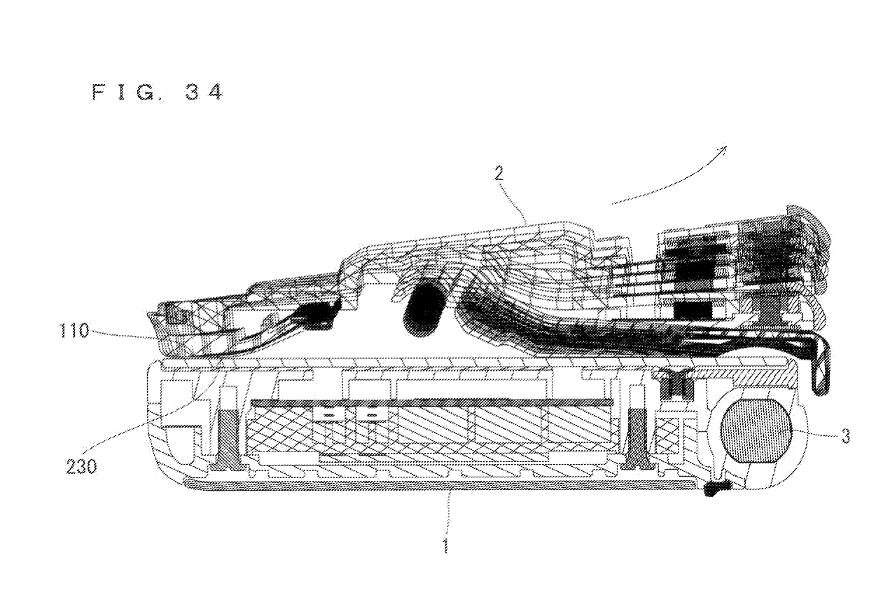

As described above, in the process of shifting from the closed state to the tilted state, the second casing 2 moves rearward while gradually rising its attitude from the horizontal attitude to the diagonal attitude as shown in FIG. 34. In this process, the lower end (front end) of the back surface of the second casing 2 slides on the surface 110 of the first casing 1.

However, since the flank 230 is formed on the lower end of the back surface of the second casing 2, contact pressure when the lower end of the back surface of the second casing 2 slides on the surface 110 of the first casing 1 becomes low as compared with a case where the flank 230 is not formed.

Therefore, it is possible to reduce a flaw received by the surface 110 of the first casing 1 when shifting from the closed state to the tilted state.

As described above, in the portable electronic apparatus, the lower end of the back surface of the second casing 2 moves along the surface of the surface of the first casing 1 in the process of shifting the closed state to the tilted state. However, since the flank 230 is formed on the lower end, the second casing 2 moves in a state where the flank 230 is separated from the surface of the first casing 1 or in a state where the flank 230 is slightly in contact with the surface of the first casing 1.

Therefore, the lower end of the second casing 2 does not come into contact with the surface of the first casing 1 or the lower end of the second casing 2 merely slides on the surface of the first casing 1 under slight contact pressure in the process of shifting from the closed state to the tilted state.

When the second casing 2 is opened from the closed state shown in FIG. 18(a) to the opened state shown in FIG. 18(b), the first casing 1 can be grasped with one hand, the second casing 2 is sandwiched by the other hand with fingers of the other hand put on both sides of the second casing 2, and in this state, the second casing 2 is brought up to the diagonal attitude.

At this time, in the closed state, since a tip end (portion connected to second casing) of the connecting arm 31 is covered by the first sidewall portion 212 of the sidewall 214 of the second casing 2 as shown in FIG. 26(a), fingertips of a hand which grasps the second casing 2 come into contact with both the sidewalls 214 and 214 of the second casing 2, and the user can reliably sandwich the second casing 2 without feeling pain in the fingertips.

Especially, since the finger-rest surface 215 is formed between the end surface of the first sidewall portion 212 and the end surface of the second sidewall portion 212, fingertips can be put on the finger-rest surface 215 when the fingertips sandwich the second casing 2 in the closed state. Accordingly, it is possible to reliably pick up the second casing 2.

Thereafter, when the state of the portable electronic apparatus slightly passes through the state shown in FIG. 26(d), the connecting arm 31 further rotates in the clockwise direction as shown in FIG. 27(a) by biasing action of the hinge unit 4, and the connecting arm 31 is softly latched at the rotation angle of the tilted state as shown in FIG. 27(b). The second casing 2 turns in the counterclockwise direction by biasing action of the torsion spring 6, the slide surface 29 abuts against the receiving surface 33 of the connecting arm 31. Accordingly, the second casing 2 is held in the attitude of the tilted state shown in FIG. 27(b).

Therefore, only by pressing the second casing 2 rearward and slightly moving the second casing 2 in the closed state shown in FIG. 26(a), the second casing 2 thereafter automatically moves to the tilted state shown in FIG. 27(b).

Next, if the second casing 2 is pressed rearward in the tilted state shown in FIG. 27(b) and the connecting arm 31 is slightly rotated in the clockwise direction, thereafter, the slide surface 29 of the second casing 2 abuts against the receiving surface 33 of the connecting arm 31 and in this state, the connecting arm 31 rotates to the rotation angle of the first opened state shown in FIG. 27(c) by the biasing action of the hinge unit 4, and the connecting arm 31 is received by the first casing 1 at this rotation angle.

As the connecting arm 31 rotates, the second casing 2 turns rearward and eventually, the first display surface 11 and the second display surface 21 are aligned on the same plane.

Further, if the second casing 2 is pulled from the first opened state shown in FIG. 27(c) toward the first casing 1, the slide surface 29 of the second casing 2 slides on the receiving surface 33 of the connecting arm 31, the second casing 2 horizontally moves to a slide-fully opened position shown in FIG. 27(d), and eventually the second casing 2 abuts against the first casing 1.

As a result, the first display surface 11 and the second display surface 21 approach each other as shown in FIG. 7, and both the display surfaces 11 and 21 form one large screen.

In the second opened state, the protrusion 10 of the first casing 1 and the recess 20 of the second casing 2 engage with each other as shown in FIG. 15(b), and both the casings 1 and 2 are connected to each other. Therefore, even if the second display surface 21 is strongly touched in this state, the second casing 2 maintains a constant attitude with respect to the first casing 1.

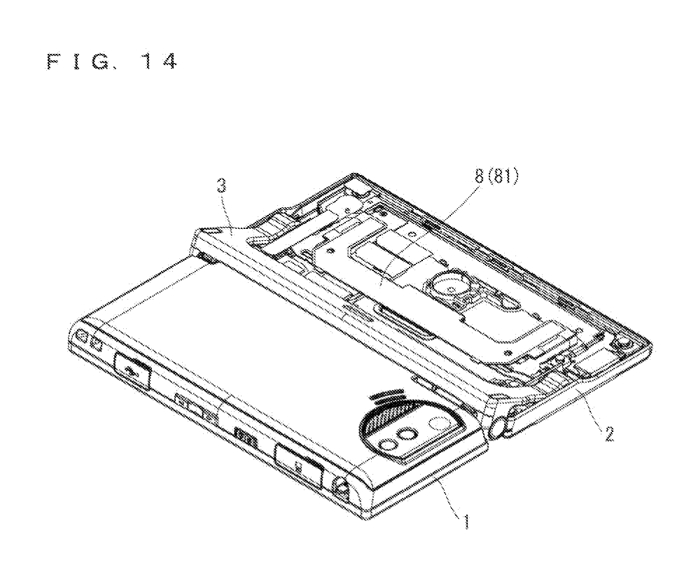

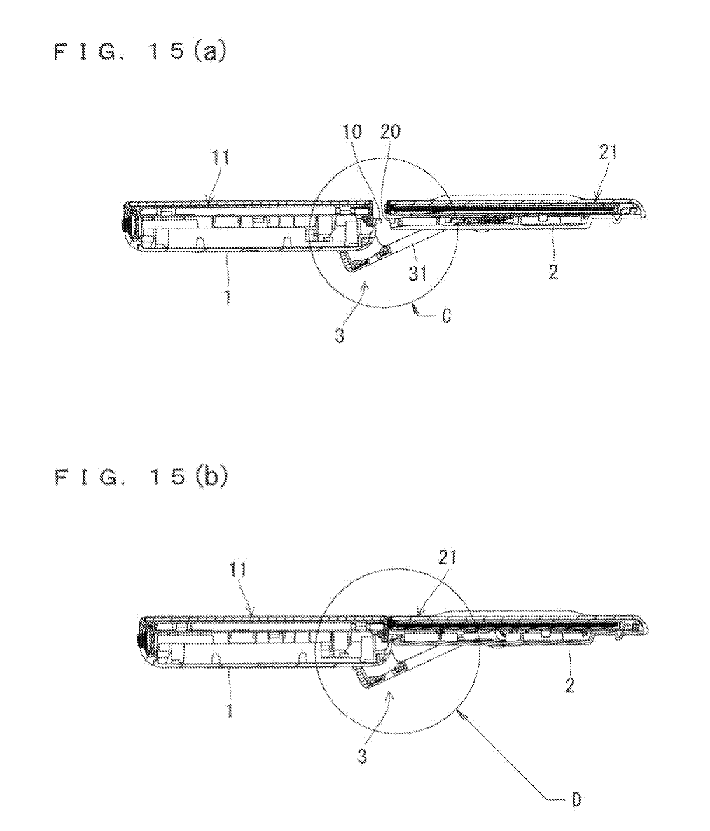

FIGS. 17(a), 17(b), and 17(c) show bending deformation of the flexible lead 7 in a process from the closed state to the second opened state through the first opened state.

In the closed state shown in FIG. 17(a), as described above, the sliding-contact surface 311 formed on the second arm portion 36 of the connecting arm 31 and the sliding-contact receiving surface 211 formed on the second casing 2 abut against each other to prevent the second casing 2 from sliding in a direction shown by an arrow of a chain double-dashed line.

Next, in the first opened state shown in FIG. 17(b), as the connecting arm 31 turns, the flexible lead 7 is greatly bent and deformed between the second lead portion 72 and the third lead portion 73.

As shown by an arrow in FIG. 17(b), if the second casing 2 is slid forward (leftward in FIG. 17(b)) by a distance T from the state shown in FIG. 17(b), the state of the portable electronic apparatus reaches the second opened state shown in FIG. 17(c). In this process, a bent portion of the flexible lead 7 between the second lead portion 72 and the third lead portion 73 is displaced forward with a greater curvature.

In the portable electronic apparatus, in the closed state shown in FIG. 17(a), the second casing 2 is prevented from moving in a direction shown by an arrow of a dashed line in FIG. 17(a). Therefore, it is possible to shorten a length of the flexible lead 7 by a margin length to be given to the flexible lead 7 when the second casing 2 is slid by action of the slide mechanism 8.

Therefore, the flexible lead 7 can be formed into a length while taking into account only bending deformation of the flexible lead 7 caused by turning action of the connecting arm 31 shown in FIGS. 17(a) to 17(c). Accordingly, it is possible to suppress the sag of the flexible lead 7 in the closed state shown in FIG. 17(a) to a minimum necessary level.

In the portable electronic apparatus, as shown in FIG. 23, the engagement piece 216 integrally projects from the front surface cabinet 2a made of synthetic resin, and the engagement receiving piece 222 integrally projects from the holder member 221 made of stainless steel. Therefore, the engagement piece 216 made of synthetic resin and the engagement receiving piece 222 made of stainless steel engage with each other.

The hook structure configured by the engagement piece made of synthetic resin and the engagement receiving piece made of stainless steel is also employed for latching of the first display 12 in the first casing 1 (not shown).

Therefore, as compared with a conventional configuration in which an engagement piece and an engagement receiving piece both made of synthetic resin engage with each other, since the material of the engagement receiving piece is changed from synthetic resin to stainless steel, its thickness is reduced (about 1.0 mm on both first casing side and second casing side in the example above), and a gap between the first display 12 and the second display 22 in the second opened state is reduced by this reduced thickness.

Accordingly, when both the display surfaces 11 and 21 are combined as one screen and a large image is displayed thereon in a state where the two display surfaces 11 and 21 are aligned on the same plane as shown in FIG. 7 (second opened state), an excellent image display having slight discontinuity is realized.

In the portable electronic apparatus, by applying a turning force acting toward the tilted state to the second casing 2 in the second opened state, the first casing 1 and the second casing 2 can be directly shifted from the second opened state to the tilted state without passing through the first opened state.

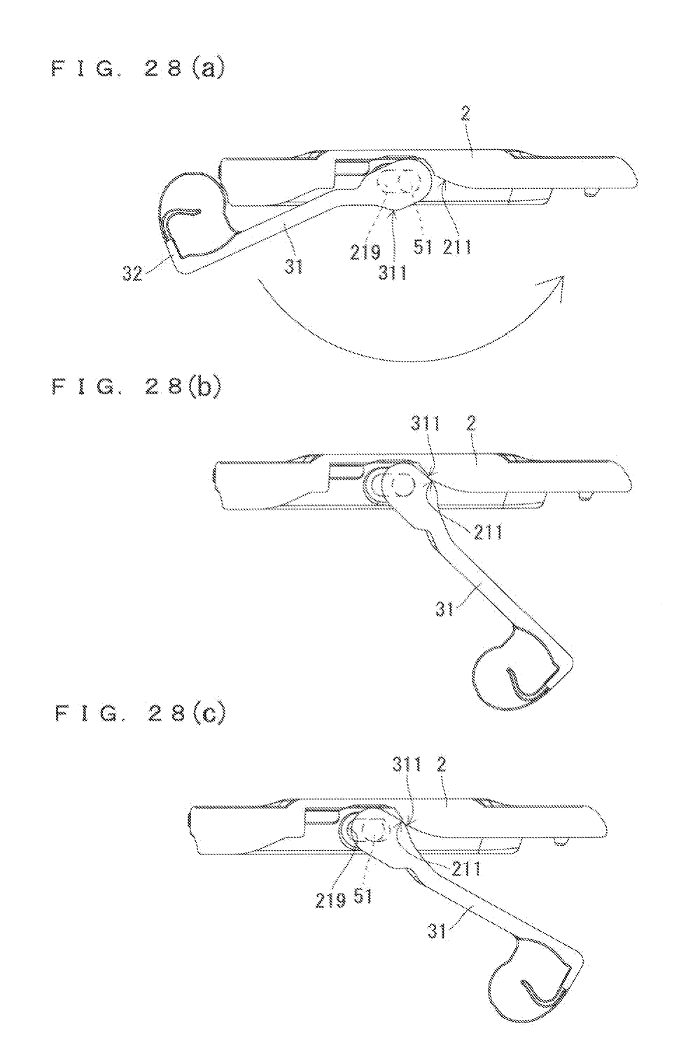

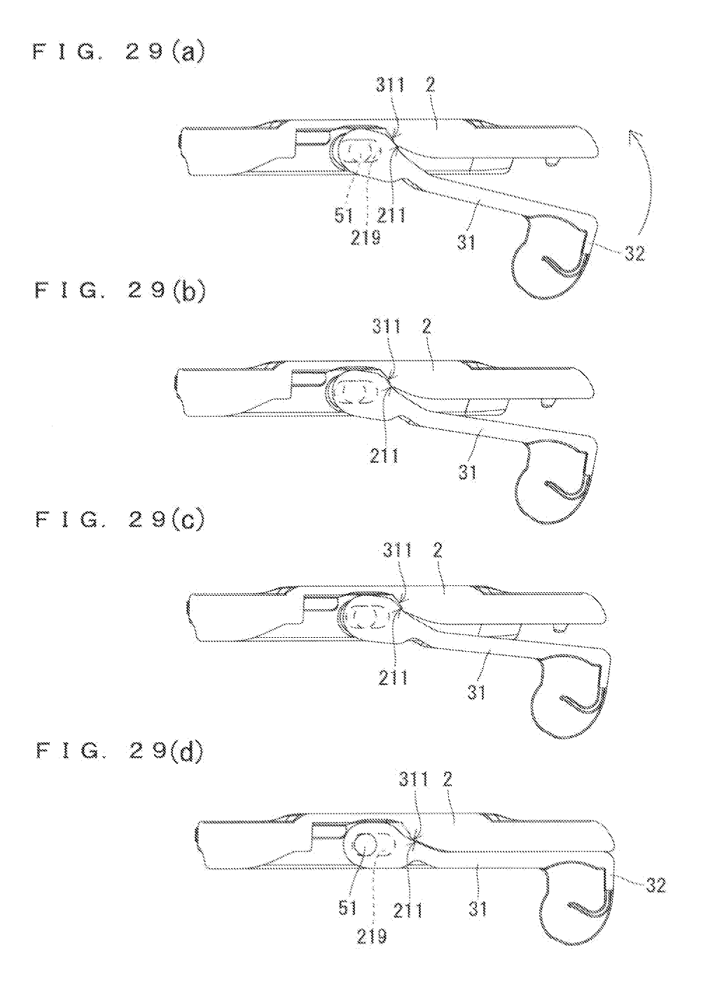

FIGS. 28(a) to 28(c) and FIGS. 29(a) to 29(d) show, on the basis of the second casing 2 as a reference, sliding action of the sliding-contact surface 311 of the connecting arm 31 on the sliding-contact receiving surface 211 of the second casing 2 in a process from the second opened state to the closed state through the tilted state.

In the second opened state, the sliding-contact surface 311 of the connecting arm 31 and the sliding-contact receiving surface 211 of the second casing 2 separate from each other as shown in FIG. 28(a), and if the connecting arm 31 turns as shown by an arrow from this state, the sliding-contact surface 311 of the connecting arm 31 sliding-contacts with the sliding-contact receiving surface 211 of the second casing 2 as shown in FIG. 28(b).

Thereafter, the connecting arm 31 turns to the closed state shown in FIG. 29(d), the sliding-contact surface 311 of the connecting arm 31 slides on the sliding-contact receiving surface 211 of the second casing 2 as shown in FIGS. 28(b) and 28(c) and FIGS. 29(a) to 29(d). By a cam function caused by this sliding action, a pivot (hinge members 5 and 51) on the side of the second casing 2 of the connecting arm 31 relatively moves in a sliding direction (leftward in the drawing) of the slide mechanism 8 to the second casing 2.

In the closed state shown in FIG. 29(d), the sliding-contact surface 311 of the connecting arm 31 remains sliding-contacted with the sliding-contact receiving surface 211 of the second casing 2, and the pivot (hinge members 5 and 51) on the side of the second casing 2 of the connecting arm 31 reaches the slide movement end.

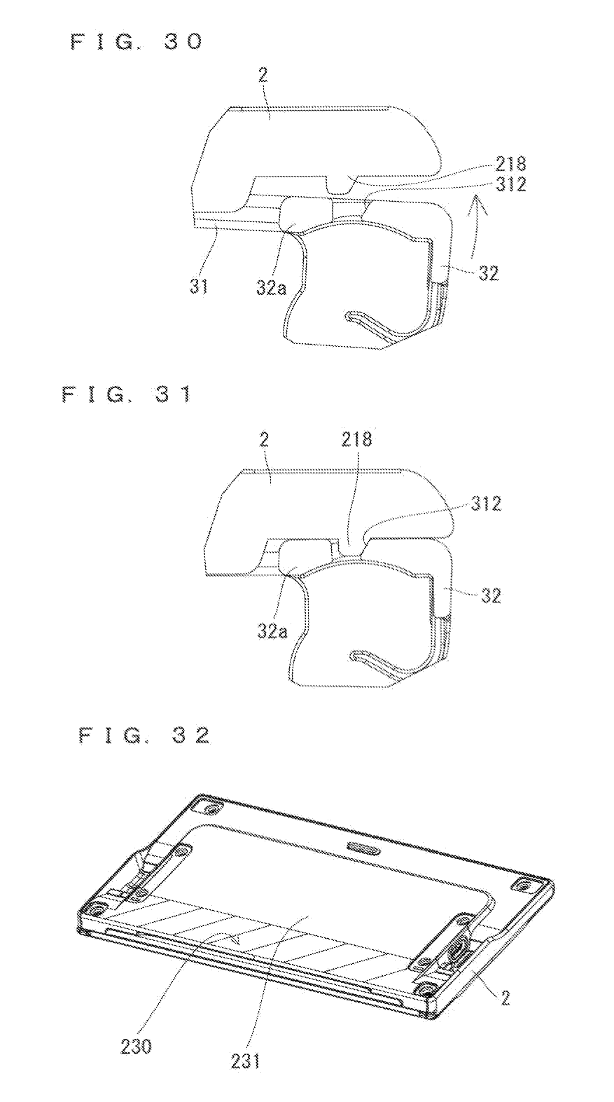

As described above, in the process from the second opened state to the closed state through the tilted state, the sliding-contact surface 311 of the connecting arm 31 slides on the sliding-contact receiving surface 211 of the second casing 2, so that the second casing 2 moves in a sliding direction (rightward in the drawing) of the slide mechanism relative to the connecting member 32. At the final stage shown in FIGS. 29(c) and 29(d), as shown in FIGS. 30 and 31, the protrusion 218 of the second casing 2 is fitted into the through hole 312 of the connecting member 32, and the protrusion 218 of the second casing 2 engages with the through hole 312 of the connecting member 32.

In the portable electronic apparatus, in the closed state, the protrusion 218 and the recess 218 provided on opposed surfaces of the connecting member 32 and the second casing 2 engage with each other, and a relative position of both the casings in the sliding direction is defined.

In the second opened state, since the gap between the surface of the first casing 1 and the surface of the second casing 2 is minimized, display surfaces provided on both the surfaces are combined as one screen in a state where both the surfaces are aligned on the same plane, and an image having almost no discontinuity can be displayed.

In a state where the protrusion 218 of the second casing 2 engages with the through hole 312 of the connecting member 32, the sliding-contact surface 311 of the connecting arm 31 and the sliding-contact receiving surface 211 of the second casing 2 maintain the mutually sliding-contact state or the sliding-contact surface 311 of the connecting arm 31 slightly separates from the sliding-contact receiving surface 211 of the second casing 2.

Therefore, in the closed state, as shown in FIG. 29(d), the sliding-contact receiving surface 211 of the second casing 2 abuts against or is opposed to the sliding-contact surface 311 of the connecting arm 31 to prevent the second casing 2 from moving forward (leftward in the drawing), and as shown in FIG. 31, the rear end surface of the protrusion 218 of the second casing 2 abuts against a rear inner peripheral surface of the through hole 312 of the connecting member 32 to prevent the second casing 2 from moving rearward (rightward in the drawing).

In this manner, the position of the second casing 2 with respect to the first casing 1 in the closed state is defined to a constant position or is defined within a constant range, and a position of the second casing 2 is fixed.

As described above, according to this portable electronic apparatus, even if a rotation force acting toward the tilted state is applied to the second casing 2 in the second opened state, and the second casing 2 is shifted from the second opened state to the closed state without passing through the first opened state, the second casing 2 is moved to a predetermined position with respect to the first casing 1 in the closed state, and the protrusion 218 of the second casing 2 can engage with the through hole 312 of the connecting member 32.

In the portable electronic apparatus, if the first casing 1 and the second casing 2 are shifted from the second opened state to the closed state, the connecting member 32 turns, and according to this turning action, the sliding-contact surface 311 and the sliding-contact receiving surface 211 sliding-contact with each other. Further, the slide mechanism 8 operates by receiving a force in the sliding direction by cam action caused by mutual sliding between the sliding-contact surface 311 and the sliding-contact receiving surface 211, and the second casing 2 moves in the sliding direction relative to the connecting member 32.

As a result, a position of the second casing 2 in the sliding direction relative to the connecting member in the second opened state is displaced to a predetermined relative position in the closed state.

Although the second casing 2 is provided with the protrusion 218 and the connecting member 32 is provided with the through hole 312 to be the recess in the above example, the present invention is not limited thereto. For example, the second casing 2 may be provided with the recess and the connecting member 32 may be provided with the protrusion. Moreover, the present invention is not limited to the recess and the protrusion, and it is possible to employ a latching structure capable of preventing the second casing 2 from sliding in the closed state.

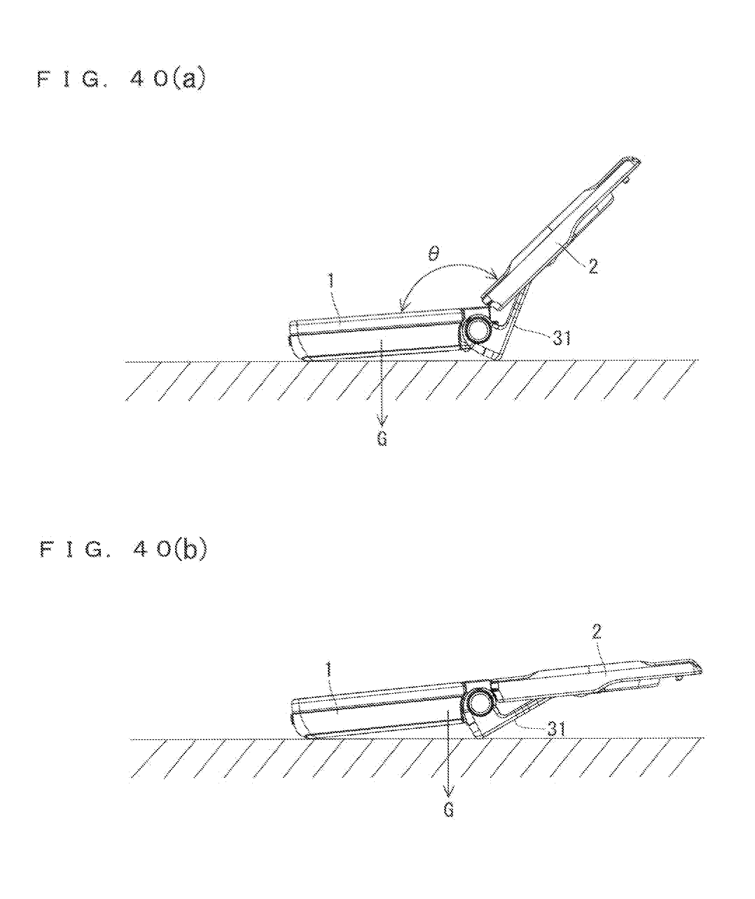

When the portable electronic apparatus is placed on the desk in the tilted state as shown in FIG. 40(a) or when it is placed on the desk in the second opened state as shown in FIG. 40(b), an angle portion of the connecting arm 31 projects from the back surface of the first casing 1, and the front end of the first casing 1 and the angle portion of the connecting arm 31 come into contact.

Here, dispositions of parts with respect to the first casing 1 and the second casing 2 and an L-shape of the connecting arm 31 are designed such that a barycenter G comes closer to the first casing 1 than the contact point of the connecting arm 31 in any states as shown in the drawing. Accordingly, attitudes of both the casings 1 and 2 are stabilized.

Therefore, when the portable electronic apparatus is placed on the desk in the tilted state as shown in FIG. 40(a), it is possible to operate the touch panel of the front first casing 1 while viewing the display of the rear second casing 2, for example.

When the portable electronic apparatus is placed on the desk in the second opened state as shown in FIG. 40(b), both the display surfaces 11 and 21 are slightly oriented toward a user in accordance with a projecting amount of the angle portion of the connecting arm 31. Thus, both the display surfaces 11 and 21 may form one screen for example, and it is possible to view an image on a large screen. In this case, since both the display surfaces 11 and 21 sufficiently approach each other, it is possible to display an image having almost no discontinuity on both the display surfaces 11 and 21.

Furthermore, in the portable electronic apparatus, when the apparatus falls on a floor surface, if it takes a falling attitude in which the front end surface of the second casing 2 is oriented downward, one of the pair of protrusions 200 and 200 formed on the front end surface first collides against the floor surface, and immediately after that, the other protrusion 200 collides against the floor surface.

As shown in FIG. 20, the second display 22 is disposed close to the front end surface of the second casing 2 as close as possible, and the glass plate 24 is disposed to cover the second display 22. Hence, a distance between the front end surface of the glass plate 24 and the front end surface of the second casing 2 is extremely small, and when an impact force is applied to the front end surface of the second casing 2, the impact force is transmitted to the glass plate 24, and the glass plate 24 is damaged in some cases.

However, in the portable electronic apparatus, the pair of protrusions 200 and 200 are located at positions deviated from the glass plate 24 of the second casing 2 in the thickness direction and at positions deviated from the second display 22 in the width direction. The protrusion 200 exerts shock-absorbing function in accordance with a height thereof. Therefore, as compared with a case where the front end surface on which the protrusion 200 is not formed collides against the floor surface, impact forces applied to the second display 22 and the glass plate 24 which covers the second display 22 are greatly reduced.

As a result, damages of the glass plate 24 and the second display 22 caused by the impact force are reduced.

A falling impact force may be similarly applied to the glass plate 16 of the first casing 1, but in the closed state, since the rear end surface of the first casing 1 is covered by the connecting member 32 shown in FIG. 9, it is possible to reduce the impact force exerted on the glass plate 16 of the first casing 1.

### DESCRIPTION OF REFERENCE CHARACTERS

1 first casing
11 first display surface
12 first display
16 glass plate
110 surface
2 second casing
21 second display surface
22 second display
29 slide surface
24 glass plate
211 sliding-contact receiving surface
200 protrusion
214 sidewall
215 finger-rest surface
216 engagement piece
218 protrusion
221 holder member
222 engagement receiving piece
223 hole
230 flank
231 back surface
3 connecting mechanism
31 connecting arm
35 first arm portion
36 second arm portion
33 receiving surface
311 sliding-contact surface
312 through hole
4 hinge unit
42 fixed cam piece
43 movable cam piece
47 spring
5 hinge member
6 torsion spring
7 flexible lead
8 slide mechanism
83 slide member
92 magnetic sensor
93 magnet

1. A portable electronic apparatus in which a first casing and a second casing connected to each other by a connecting member and a slide mechanism interposed between the connecting member and one of the casings, the apparatus being capable of selectively setting at least three states including: a closed state wherein a surface of the first casing is covered by a back surface of the second casing, and a surface of the second casing is exposed; a first opened state wherein the second casing is moved from the closed state by turning motion of the connecting member, and surfaces of both the casings are exposed on a same plane; and a second opened state wherein motion of the slide mechanism causes both the casings to approach each other from the first opened state while the surfaces of both the casings are exposed on the same plane,
the apparatus being characterized in that the connecting member and one of the casings have opposed surfaces formed with a sliding-contact surface and a sliding-contact receiving surface, to slide against each other in a process of shifting from a second opened state to a closed state, to thereby displace from a position in a sliding direction relative to the connecting member in the second opened state to a predetermined relative position in the closed state.

2. The portable electronic apparatus according to claim 1, wherein opposed surfaces of the connecting member and the one casing in the closed state are provided with a protrusion and a recess which engage with each other in a direction intersecting with a sliding direction of the slide mechanism in the closed state.

3. The portable electronic apparatus according to claim 1, wherein the connecting member includes a pair of left and right connecting arms projecting from both ends of an arm-connecting portion, one ends of both the connecting arms are connected to both left and right ends of the first casing, other ends of both the connecting arms are connected to both left and right ends of the second casing by the slide mechanism, and the sliding-contact surface and the sliding-contact receiving surface are formed on opposed surfaces of the connecting arm and the second casing.

4. The portable electronic apparatus according to claim 1, wherein the connecting member includes a pair of left and right connecting arms projecting from both ends of an arm-connecting portion, one ends of the connecting arms are connected to the first casing by a first pivot, the other ends of the connecting arms are connected to the second casing by a second pivot which is parallel to the first pivot, the other ends can rotate between a rotation angle of the closed state and a rotation angle of the first opened state, the slide mechanism includes a slide member which is slidably disposed on the second casing, and the other ends of the connecting arms are pivotally supported by the slide member.

5. A portable electronic apparatus in which a first casing and a second casing connected to each other by a connecting member and a slide mechanism interposed between the connecting member and one of the casings, the apparatus being capable of selectively setting at least three states including: a closed state wherein a surface of the first casing is covered by a back surface of the second casing, and a surface of the second casing is exposed; a first opened state wherein the second casing is moved from the closed state by turning motion of the connecting member, and surfaces of both the casings are exposed on a same plane; and a second opened state wherein motion of the slide mechanism causes both the casings to approach each other from the first opened state while the surfaces of both the casings are exposed on the same plane,
the apparatus being characterized in that the apparatus comprises a latching structure which prevents the connecting member and the one casing from relatively sliding in a sliding direction of the slide mechanism in the closed state.

6. The portable electronic apparatus according to claim 5, wherein the latching structure includes a protrusion and a recess, which are provided on opposed surfaces of the connecting member and the one casing in the closed state, and which engage with each other in a direction intersecting with the sliding direction of the slide mechanism in the closed state.

7. The portable electronic apparatus according to claim 6, wherein the connecting member includes a pair of left and right connecting arms projecting from both ends of an arm-connecting portion, one ends of both the connecting arms are connected to both left and right ends of the first casing, other ends of both the connecting arms are connected to both left and right ends of the second casing by the slide mechanism, the protrusion is formed on the second casing, and a through hole to be the recess is formed in the arm-connecting portion.

8. The portable electronic apparatus according to claim 5, wherein the connecting member includes a pair of left and right connecting arms projecting from both ends of an arm-connecting portion, one ends of the connecting arms are connected to the first casing by a first pivot, the other ends of the connecting arms are connected to the second casing by a second pivot which is parallel to the first pivot, the other ends can rotate between a rotation angle of the closed state and a rotation angle of the first opened state, the slide mechanism includes a slide member which is slidably disposed on the second casing, and the other ends of the connecting arms are pivotally supported by the slide member.

9. The portable electronic apparatus according claim 5, wherein a sliding-contact surface and a sliding-contact receiving surface are formed on opposed surfaces between the connecting arm and the one casing, the sliding-contact surface and the sliding-contact receiving surface slide on each other in a process of shifting from the second opened state to the closed state, and the sliding-contact surface and the sliding-contact receiving surface causes a relative position of the connecting arm and the one casing to change to a relative position where the protrusion and the recess engage with each other in the closed state.

10. A portable electronic apparatus in which a first casing and a second casing connected to each other by a connecting mechanism, the apparatus being capable of selectively setting at least two states including: a closed state wherein a surface of the first casing is covered by a back surface of the second casing, and a surface of the second casing is exposed; and a tilted state wherein the second casing is moved from the closed state by turning action of the connecting mechanism, the surface of the second casing is inclined by an opening angle of 90° or more and less than 180° with respect to the surface of the first casing, and the surfaces of both the casings are exposed,
the apparatus being characterized in that a cam mechanism is incorporated in the connecting mechanism, the cam mechanism imparts a torque to turning action of the connecting mechanism, a cam curve of the cam mechanism includes a peak to function in a shifting process from the closed state to the tilted state, and a valley to function in the tilted state, a torque generated in the cam mechanism at an apex of the peak is set to a value greater than a first torque value T1 which is applied to the cam mechanism by a weight of the first casing, and a torque generated by the cam mechanism in the closed state is set to a second torque value T2 which is smaller than the first torque value T1.

11. The portable electronic apparatus according to claim 10, wherein the cam mechanism includes a pair of cam pieces which rotate relative to each other as both the casings relatively move between the closed state and the tilted state, and a spring which brings cam faces of both the cam pieces into contact with each other under pressure.

12. The portable electronic apparatus according to claim 10, wherein surfaces of the first casing and the second casing are respectively provided with display surfaces, an opened state in which the surfaces of both the casings are aligned on the same plane by turning action of the connecting mechanism is further set, and a cam curve of the cam mechanism includes a second peak to function in a shifting process from the tilted state to the opened state.

13. The portable electronic apparatus according to claim 10, wherein the connecting mechanism includes a pair of left and right connecting arms disposed on both sides of the first casing and the second casing, one ends of the connecting arms are connected to the first casing by a hinge unit, the other ends of the connecting arms are connected to the second casing by a hinge member, and the cam mechanism is incorporated in the hinge unit interposed between the first casing and at least one of the connecting arms.
